(19) United States
(12) Patent Application Publication
(10) Pub. No.: US 2026/0020303 A1
(43) Pub. Date: Jan. 15, 2026

(54) SEMICONDUCTOR DEVICE

(71) Applicant: ROHM CO., LTD., Kyoto-shi (JP)

(72) Inventors: Seigo MORI, Kyoto-shi (JP); Yuki NAKANO, Kyoto-shi (JP)

(73) Assignee: ROHM CO., LTD., Kyoto-shi (JP)

(21) Appl. No.: 19/329,885

(22) Filed: Sep. 16, 2025

Related U.S. Application Data
(63) Continuation of application No. PCT/JP2024/007836, filed on Mar. 1, 2024.

(30) Foreign Application Priority Data
Mar. 28, 2023 (JP) 2023-051501

(51) Int. Cl. H10D 62/13; H10D 30/01; H10D 30/66; H10D 62/10; H10D 62/17; H10D 62/832

(52) U.S. Cl. CPC H10D 62/155; H10D 30/0291; H10D 30/665; H10D 62/107; H10D 62/393; H10D 62/8325

(57) ABSTRACT

A semiconductor device includes a chip having a principal surface, a gate electrode formed on the principal surface, an interlayer film covering the gate electrode, an opening formed in the interlayer film such as to be separated from the gate electrode in a lateral direction along the principal surface and exposing a part of the chip as a contact portion, and a front surface electrode formed on the interlayer film and mechanically and electrically connected to the contact portion in the opening, wherein the contact portion includes a mesa contact portion that protrudes from the principal surface and has a mesa side portion and a mesa upper portion, and the front surface electrode covers the mesa side portion and the mesa upper portion.

### CROSS-REFERENCE TO RELATED APPLICATIONS

The present application is a continuation application of PCT Application No. PCT/JP2024/007836, filed on Mar. 1, 2024, which claims priority to Japanese Patent Application No. 2023-051501, filed on Mar. 28, 2023, in the Japan Patent Office, and the entire disclosure of these applications are incorporated herein by reference.

### TECHNICAL FIELD

The present disclosure relates to a semiconductor device.

### BACKGROUND ART

Japanese Patent Application Publication No. 2015-207588 discloses an SiC semiconductor device including a plurality of p-type body regions formed on a front surface portion of an n⁻ type SiC semiconductor layer, each of the p-type body regions constituting a unit cell, an n-type source region formed inside the p-type body region, a gate electrode facing the p-type body region through a gate insulating film, an n⁺ type drain region and a p⁺ type collector region formed adjacent to each other on a rear surface portion of the SiC semiconductor layer, and an n⁻ type drift region between the p-type body region and the n⁺ type drain region, in which the p⁺ type collector region is formed such as to cover a region including at least two unit cells in an X-axis along a front surface of the SiC semiconductor layer.

### BRIEF DESCRIPTION OF THE DRAWINGS

FIG. 1 is a plan view illustrating a semiconductor device according to one preferred embodiment.

FIG. 2 is a cross-sectional view taken along line II-II shown in FIG. 1.

FIG. 3 is a plan view illustrating a layout example of a first principal surface.

FIG. 4 is an enlarged plan view illustrating a main portion of the first principal surface.

FIG. 5 is an enlarged plan view illustrating a further main portion of the first principal surface.

FIG. 6 is a cross-sectional view taken along line VI-VI shown in FIG. 5.

FIG. 7 is an enlarged cross-sectional view illustrating a main portion of FIG. 6.

FIG. 8 is a cross-sectional view taken along line VIII-VIII shown in FIG. 5.

FIG. 9 is an enlarged cross-sectional view illustrating a main portion of FIG. 8.

FIG. 10 is a schematic perspective view illustrating a structure of a mesa contact portion in detail.

FIG. 11 is a schematic view illustrating a wafer.

FIGS. 12A to 12O are cross-sectional views illustrating a method for manufacturing the semiconductor device.

FIG. 13 is a cross-sectional view illustrating a first modification example (second contact portion) of the mesa contact portion.

FIG. 14 is a perspective view of the mesa contact portion including the second contact portion in FIG. 13.

FIGS. 15A to 15D are views illustrating a step related to the formation of the second contact portion in FIG. 13.

FIG. 16 is a cross-sectional view illustrating a second modification example (third contact portion) of the mesa contact portion.

FIG. 17 is a perspective view of the mesa contact portion including the third contact portion in FIG. 16.

FIGS. 18A to 18D are views illustrating a step related to the formation of the third contact portion in FIG. 16.

FIG. 19 is a cross-sectional view illustrating a fourth modification example of the mesa contact portion.

FIG. 20 is a cross-sectional view illustrating a fifth modification example of the mesa contact portion.

FIG. 21 is a cross-sectional view illustrating a sixth modification example of the mesa contact portion.

### DESCRIPTION OF EMBODIMENTS

Hereinafter, preferred embodiments shall be described in detail with reference to attached drawings. The attached drawings are all schematic views and are not strictly illustrated, and relative positional relationships, scales, proportions, angles, etc., thereof do not always match. Identical reference signs are given to corresponding structures among the attached drawings, and duplicate descriptions thereof shall be omitted or simplified. For the structures whose description has been omitted or simplified, the description given before the omission or simplification shall apply.

When the wording “substantially” is used in this description, the wording includes a numerical value (mode) equal to a numerical value (mode) of a comparison target and also includes numerical errors (mode errors) in a range of ±10% on a basis of the numerical value (mode) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type” and the “p-type” may be referred to as a “first conductivity type” and the “n-type” may be referred to as a “second conductivity type.” As a matter of course, the “n-type” may be referred to as the “first conductivity type” and the “p-type” may be referred to as the “second conductivity type” instead. The “p-type” is a conductivity type due to a trivalent element and the “n-type” is a conductivity type due to a pentavalent element. The trivalent element is at least one type among boron, aluminum, gallium, and indium. The pentavalent element is at least one type among nitrogen, phosphorus, arsenic, antimony, and bismuth.

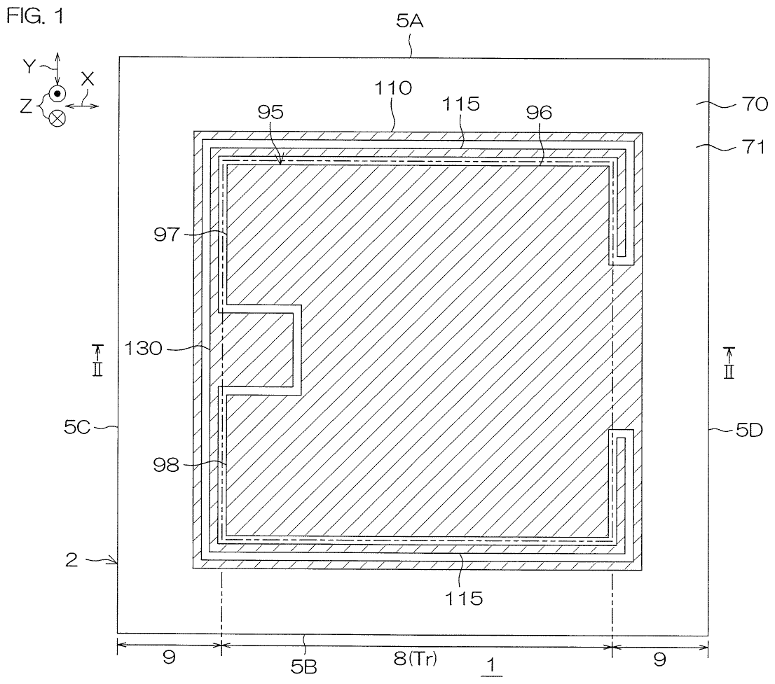

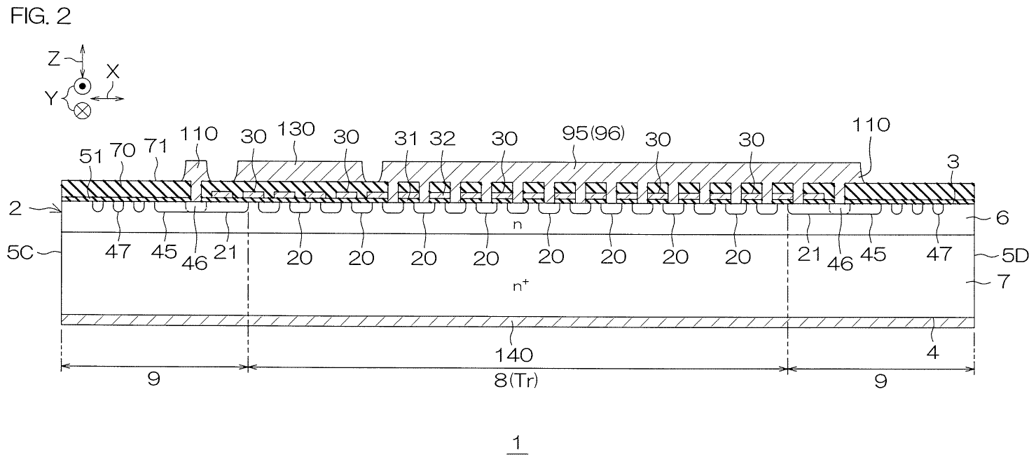

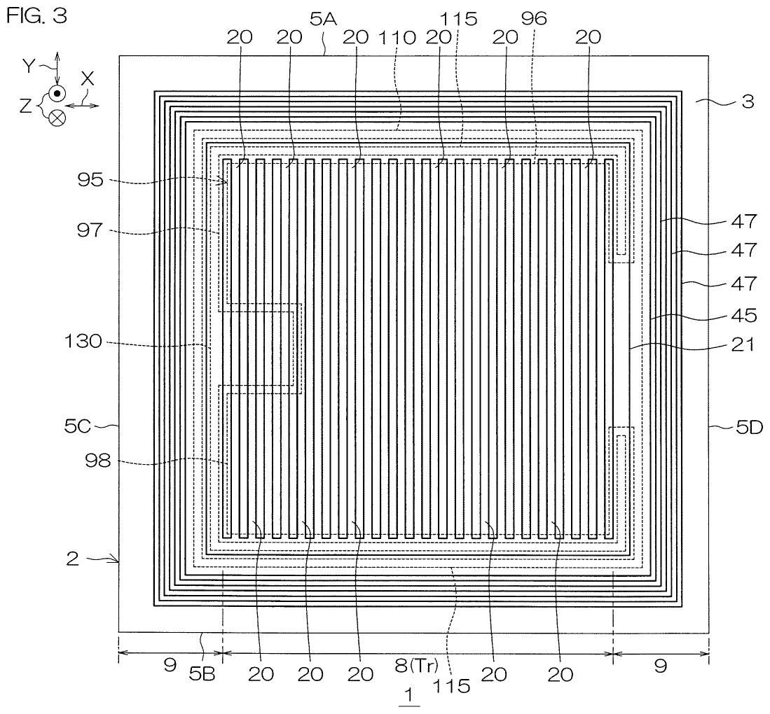

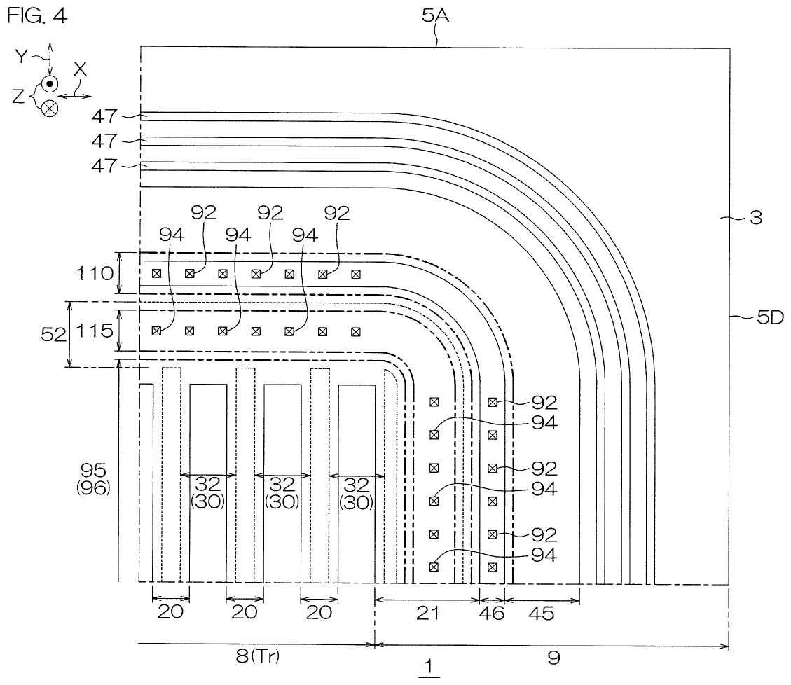

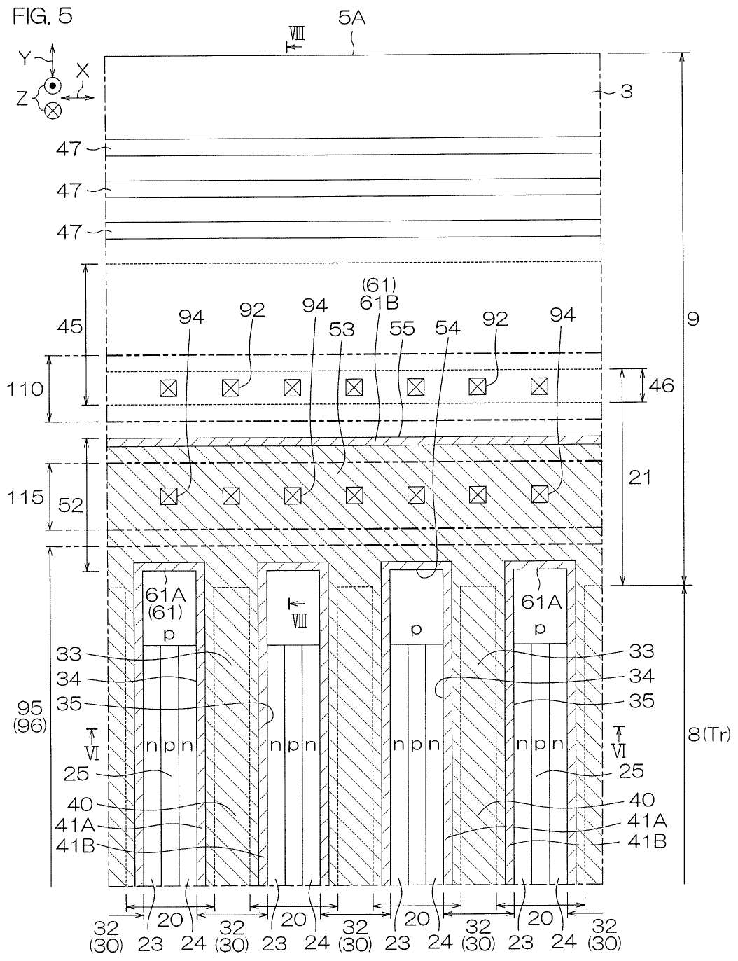

FIG. 1 is a plan view illustrating a semiconductor device 1 according to one preferred embodiment. FIG. 2 is a cross-sectional view taken along line II-II shown in FIG. 1. FIG. 3 is a plan view illustrating a layout example of a first principal surface 3. FIG. 4 is an enlarged plan view illustrating a main portion of the first principal surface 3. FIG. 5 is an enlarged plan view illustrating a further main portion of the first principal surface 3.

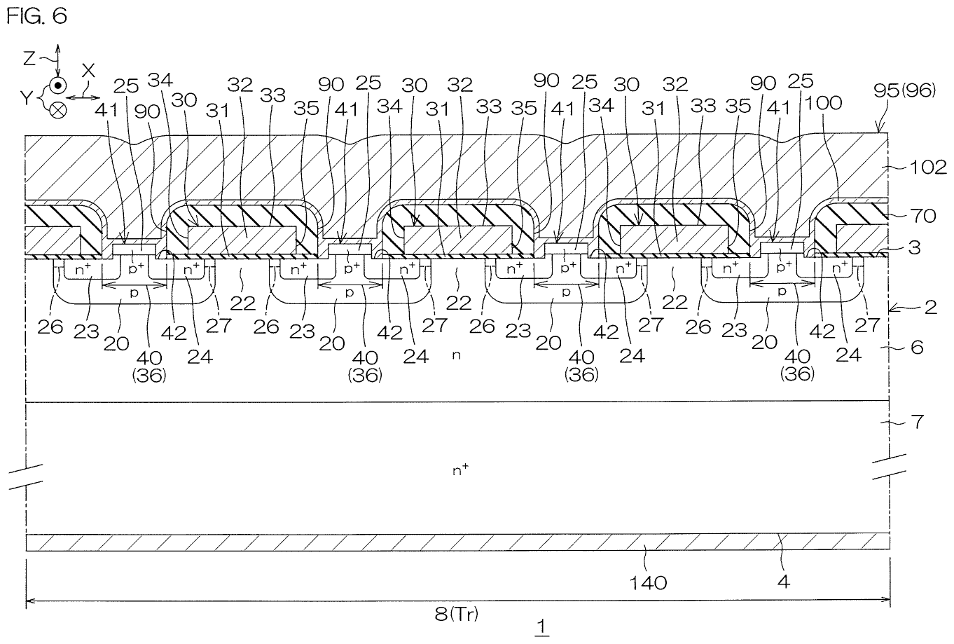

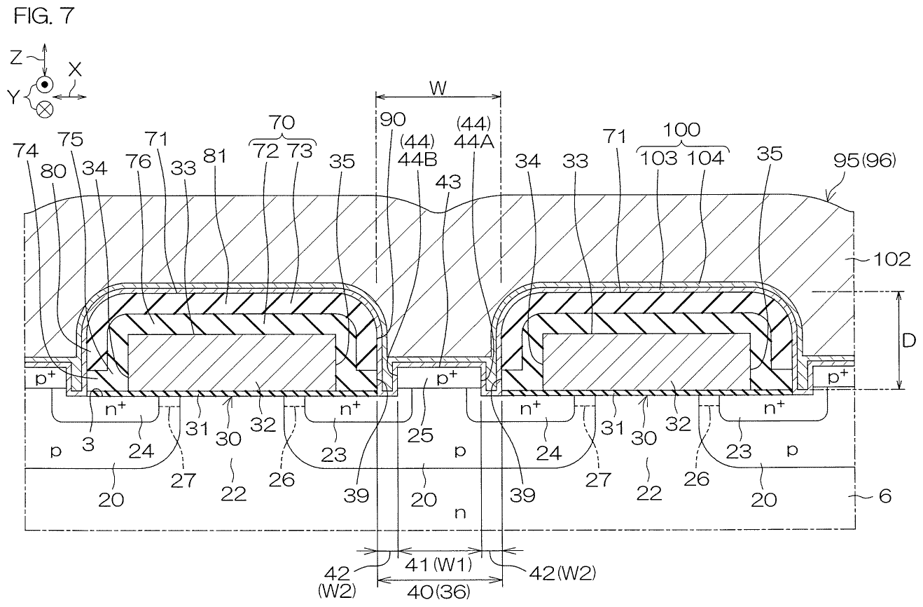

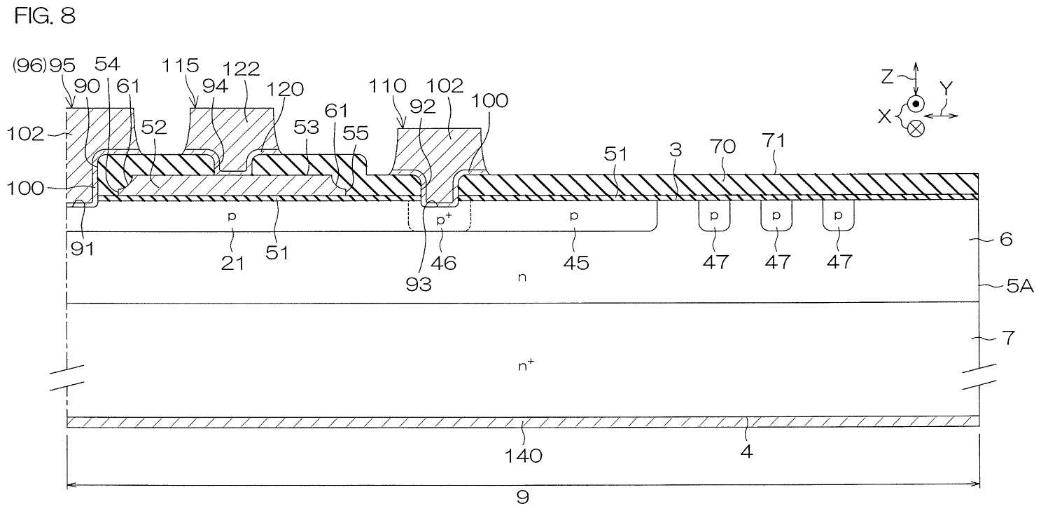

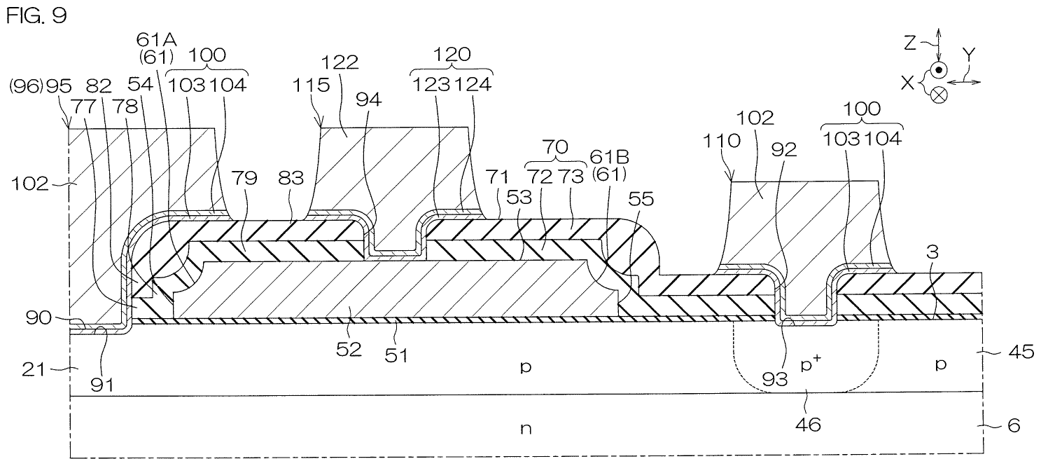

FIG. 6 is a cross-sectional view taken along line VI-VI shown in FIG. 5. FIG. 7 is an enlarged cross-sectional view illustrating a main portion of FIG. 6. FIG. 8 is a cross-sectional view taken along line VIII-VIII shown in FIG. 5. FIG. 9 is an enlarged cross-sectional view illustrating a main portion of FIG. 8.

Referring to FIGS. 1 to 9, the semiconductor device 1 is a semiconductor switching device having an insulated gate transistor structure Tr as an example of a device structure. The transistor structure Tr has a vertical structure. The semiconductor device 1 is an SiC semiconductor device having a chip 2 containing an SiC monocrystal. The chip 2 may be referred to as an “SiC chip” or as a “semiconductor chip.”

In this embodiment, the chip 2 is constituted of the SiC monocrystal, which is a hexagonal crystal, and is formed in a rectangular parallelepiped shape. The SiC monocrystal that is a hexagonal crystal has multiple polytypes including a 2H (hexagonal)-SiC monocrystal, a 4H-SiC monocrystal, a 6H-SiC monocrystal, etc. In this embodiment, an example in which the chip 2 is constituted of the 4H-SiC monocrystal is to be given, but the chip 2 may be constituted of another polytype instead.

The chip 2 has the first principal surface 3 on one side, a second principal surface 4 on another side, and first to fourth side surfaces 5A to 5D connecting the first principal surface 3 and the second principal surface 4. In plan view as viewed from a vertical direction Z (hereinafter referred to simply as “plan view”), the first principal surface 3 and the second principal surface 4 are each formed in a quadrangular shape. The vertical direction Z is also a thickness direction of the chip 2 and a normal direction to the first principal surface 3 (second principal surface 4). The first principal surface 3 and the second principal surface 4 may be formed in a square shape or a rectangular shape in plan view.

The first principal surface 3 and the second principal surface 4 are preferably formed by c-planes of the SiC monocrystal. In this case, preferably, the first principal surface 3 is formed by a silicon plane ((0001) plane) of the SiC monocrystal and the second principal surface 4 is formed by a carbon plane ((000-1) plane) of the SiC monocrystal.

The first side surface 5A and the second side surface 5B extend in a first direction X along the first principal surface 3 and face each other in a second direction Y intersecting the first direction X along the first principal surface 3. Specifically, the second direction Y is orthogonal to the first direction X. The third side surface 5C and the fourth side surface 5D extend in the second direction Y and face each other in the first direction X.

In the following description, one side in the first direction X means the third side surface 5C side, and the other side in the first direction X means the fourth side surface 5D side. Also, one side in the second direction Y means the first side surface 5A side, and the other side in the second direction Y means the second side surface 5B side. In this embodiment, the first direction X is an m-axis direction ([1-100] direction) of the SiC monocrystal and the second direction Y is an a-axis direction ([11-20] direction) of the SiC monocrystal. As a matter of course, the first direction X may instead be the a-axis direction of the SiC monocrystal and the second direction Y may instead be the m-axis direction of the SiC monocrystal.

The chip 2 (the first principal surface 3 and the second principal surface 4) has an off angle inclined at a predetermined angle in a predetermined off direction with respect to the c-plane of the SiC monocrystal. That is, a c-axis ((0001) axis) of the SiC monocrystal is inclined by just the off angle toward the off direction from the vertical axis. Also, the c-plane of the SiC monocrystal is inclined by just the off angle with respect to the horizontal plane.

The off direction is preferably the a-axis direction (that is, the second direction Y) of the SiC monocrystal. The off angle may exceed 0° and be 10° or less. The off angle may have a value belonging to at least one range among exceeding 0° and being 1° or less, being 1° or more and 2.5° or less, being 2.5° or more and 5° or less, being 5° or more and 7.5° or less, and being 7.5° or more and 10° or less.

The off angle is preferably 5° or less. The off angle is particularly preferably 2° or more and 4.5° or less. The off angle is typically set in a range of 4°±0.1°. This description does not exclude an embodiment in which the off angle is 0° (that is, an embodiment in which the first principal surface 3 is a just surface with respect to the c-plane).

The semiconductor device 1 includes a first semiconductor region 6 of the n-type that is formed in a region (surface layer portion) inside the chip 2 at the first principal surface 3 side. The first semiconductor region 6 may be referred to as a “drift region,” a “drain drift region,” a “drain region,” etc. A drain potential as a high potential (first potential) is applied to the first semiconductor region 6. The first semiconductor region 6 is formed in a layer shape extending along the first principal surface 3 and is exposed from the first principal surface 3 and the first to fourth side surfaces 5A to 5D. In this embodiment, the first semiconductor region 6 consists of an epitaxial layer (specifically, an SiC epitaxial layer).

The semiconductor device 1 includes a second semiconductor region 7 of the n-type that is formed in a region (surface layer portion) inside the chip 2 at the second principal surface 4 side. A drain potential is applied to the second semiconductor region 7. The second semiconductor region 7 may be referred to as a “drain region,” etc. The second semiconductor region 7 has an n-type impurity concentration higher than that of the first semiconductor region 6 and is electrically connected to the first semiconductor region 6 inside the chip 2.

The second semiconductor region 7 is formed in a layer shape extending along the second principal surface 4 and is exposed from the second principal surface 4 and the first to fourth side surfaces 5A to 5D. In this embodiment, the second semiconductor region 7 consists of a semiconductor substrate (specifically, an SiC substrate). That is, the chip 2 has a laminated structure including the semiconductor substrate and the epitaxial layer. The second semiconductor region 7 has a thickness larger than the thickness of the first semiconductor region 6.

The semiconductor device 1 includes an active region 8 that is set in the chip 2. The active region 8 is a region that includes a device structure (transistor structure Tr) and in which an output current (drain current) is generated. The active region 8 is set in an inner portion of the chip 2 at intervals from peripheral edges (the first to fourth side surfaces 5A to 5D) of the chip 2 in plan view. The active region 8 is set in a polygonal shape (in this embodiment, a quadrangular shape) having four sides parallel to the peripheral edges of the chip 2 in plan view. A plane area of the active region 8 is preferably 50% or more and 90% or less of the plane area of the first principal surface 3.

The semiconductor device 1 includes an outer peripheral region 9 that, in the chip 2, is set outside the active region 8. The outer peripheral region 9 is provided in a region between the peripheral edges of the chip 2 and the active region 8 in plan view. The outer peripheral region 9 extends in a band shape along the active region 8 and is set to a polygonal annular shape (in this embodiment, a quadrangular annular shape) that surrounds the active region 8 in plan view.

The semiconductor device 1 includes a plurality of p-type body regions 20 formed in a surface layer portion of the first principal surface 3 in the active region 8. A source potential as a low potential (second potential) different from a high potential (first potential) is applied to the plurality of body regions 20. The plurality of body regions 20 are arranged at intervals in the first direction X, and each formed in a band shape extending in the second direction Y. That is, the plurality of body regions 20 are arranged in a stripe shape extending in the second direction Y.

The plurality of body regions 20 are formed at intervals from a bottom portion of the first semiconductor region 6 toward the first principal surface 3, and face the second semiconductor region 7 across a part of the first semiconductor region 6. The plurality of body regions 20 are preferably formed at intervals from an intermediate portion of the first semiconductor region 6 toward the first principal surface 3. The plurality of body regions 20 are exposed from the first principal surface 3.

The semiconductor device 1 includes a p-type outer body region 21 formed in the surface layer portion of the first principal surface 3 in the outer peripheral region 9. The outer body region 21 preferably has a p-type impurity concentration substantially equal to the p-type impurity concentration of the body region 20. As a matter of course, the p-type impurity concentration of the outer body region 21 may be less than the p-type impurity concentration of the body region 20, or may be higher than the p-type impurity concentration of the body region 20.

The outer body region 21 is formed at intervals from the peripheral edges (the first to fourth side surfaces 5A to 5D) of the first principal surface 3 toward the active region 8, and extends in a band shape along the active region 8. The outer body region 21 has a portion extending in a band shape in the first direction X and a portion extending in a band shape in the second direction Y in plan view, and demarcates the active region 8 from a plurality of directions.

In this embodiment, the outer body region 21 surrounds the active region 8 in plan view and is demarcated in a polygonal annular shape (in this embodiment, a quadrangular annular shape) having four sides parallel to the peripheral edges of the first principal surface 3. That is, the outer body region 21 forms a boundary portion between the active region 8 and the outer peripheral region 9. The outer body region 21 may have an edge portion connecting the portion extending in the first direction X and the portion extending in the second direction Y in plan view in an arcuate shape (preferably a quadrant arcuate shape) (see FIG. 4).

The outer body region 21 has an inner edge portion on the active region 8 side and an outer edge portion on the peripheral edge side of the first principal surface 3. The inner edge portion of the outer body region 21 is connected to the plurality of body regions 20 in the portion extending in the first direction X. Thus, the outer body region 21 is fixed at the same potential as the plurality of body regions 20.

The outer body region 21 preferably has a width larger than the width of the body region 20. The width of the body region 20 is a width in a direction orthogonal to an extension direction (that is, the first direction X). The width of the outer body region 21 is a width in a direction orthogonal to the extension direction. As a matter of course, the width of the outer body region 21 may be substantially equal to the width of the body region 20, or may be less than the thickness of the body region 20.

The ratio of the width of the outer body region 21 to the width of the body region 20 may be 10 or more and 50 or less. The width ratio is preferably 20 or more and 40 or less.

The outer body region 21 is formed at an interval from the bottom portion of the first semiconductor region 6 toward the first principal surface 3, and faces the second semiconductor region 7 across a part of the first semiconductor region 6. The outer body region 21 is preferably formed at an interval from the intermediate portion of the first semiconductor region 6 toward the first principal surface 3. The outer body region 21 is exposed from the first principal surface 3.

The outer body region 21 preferably has a thickness (depth) substantially equal to the thickness (depth) of the body region 20. As a matter of course, the thickness of the outer body region 21 may be less than the thickness of the body region 20, or may be larger than the thickness of the body region 20.

The semiconductor device 1 includes a plurality of n-type surface layer drift regions 22 formed in the surface layer portion of the first principal surface 3. In this embodiment, each of the plurality of surface layer drift regions 22 is constituted of a part of the first semiconductor region 6. As a matter of course, the plurality of surface layer drift regions 22 may have an n-type impurity concentration higher than the n-type impurity concentration of the first semiconductor region 6, or may have an n-type impurity concentration lower than the n-type impurity concentration of the first semiconductor region 6.

The plurality of surface layer drift regions 22 are each demarcated in a region between the plurality of body regions 20 adjacent to each other in the first direction X. Specifically, the plurality of surface layer drift regions 22 are each demarcated by the plurality of body regions 20 and the outer body region 21 in the surface layer portion of the first principal surface 3. The plurality of surface layer drift regions 22 are arranged at intervals in the first direction X, and each formed in a band shape extending in the second direction Y. That is, the plurality of surface layer drift regions 22 are formed in a stripe shape extending in the second direction Y.

The semiconductor device 1 includes a plurality of n-type source regions 23 and 24 formed in surface layer portions of the plurality of body regions 20, respectively. The plurality of source regions 23 and 24 have an n-type impurity concentration higher than the n-type impurity concentration of the first semiconductor region 6. A source potential is applied to the plurality of source regions 23 and 24.

The plurality of source regions 23 and 24 include a first source region 23 positioned on one side in the first direction X and a second source region 24 positioned on the other side in the first direction X in the surface layer portion of each body region 20. In this embodiment, in the first direction X, one first source region 23 is formed on one end side of the body region 20, and one second source region 24 is formed on the other end side of the body region 20.

The first source region 23 is formed at an interval from one end of the body region 20 toward the other end, and extends in a band shape along the extension direction of the body region 20. The first source region 23 is formed at an interval from the outer body region 21 in the second direction Y. That is, the first source region 23 is not formed in the outer body region 21. The first source region 23 is formed at an interval from a bottom portion of the body region 20 toward the first principal surface 3, and faces the first semiconductor region 6 across a part of the body region 20.

The second source region 24 is formed at an interval from the first source region 23 toward the other end of the body region 20. The second source region 24 is formed at an interval from the other end of the body region 20 toward the one end, and extends in a band shape along the extension direction of the body region 20. The second source region 24 is formed at an interval from the outer body region 21 in the second direction Y. That is, the second source region 24 is not formed in the outer body region 21. The second source region 24 is formed at an interval from the bottom portion of the body region 20 toward the first principal surface 3, and faces the first semiconductor region 6 across a part of the body region 20.

When the plurality of first source regions 23 are formed in one body region 20, the plurality of first source regions 23 may be formed at intervals in the extension direction of the body region 20. In this case, each of the first source regions 23 may be formed in a band shape extending in the second direction Y. Similarly, when the plurality of second source regions 24 are formed in one body region 20, the plurality of second source regions 24 may be formed at intervals in the extension direction of the body region 20. In this case, each of the second source regions 24 may be formed in a band shape extending in the second direction Y.

The semiconductor device 1 includes a plurality of p-type contact regions 25 each formed in the surface layer portion of the plurality of body regions 20 in the active region 8. The contact region 25 may be referred to as a “back gate region.” A source potential is applied to the plurality of contact regions 25. The contact region 25 has a p-type impurity concentration higher than the p-type impurity concentration of the body region 20.

In this embodiment, one contact region 25 is interposed in a region between the first source region 23 and the second source region 24 in the surface layer portion of the corresponding body region 20. The contact region 25 extends in a band shape along the extension direction of the body region 20 (the source regions 23 and 24). The contact region 25 is formed at an interval from the outer body region 21 in the second direction Y. That is, the contact region 25 is not formed in the outer body region 21. The contact region 25 is formed at an interval from the bottom portion of the body region 20 toward the first principal surface 3, and faces the first semiconductor region 6 across a part of the body region 20.

When the plurality of contact regions 25 are formed in one body region 20, the plurality of contact regions 25 may be formed at intervals in the extension direction of the body region 20. In this case, each of the contact regions 25 may be formed in a band shape extending in the second direction Y.

The semiconductor device 1 includes a plurality of p-type channel regions 26 and 27 formed in the surface layer portion of the first principal surface 3. The plurality of channel regions 26 and 27 are demarcated in regions between end portions of the plurality of body regions 20 (the plurality of surface layer drift regions 22) and peripheral edges of the plurality of source regions 23 and 24, respectively, in the surface layer portions of the plurality of body regions 20. In this embodiment, the plurality of channel regions 26 and 27 are arranged at intervals in the first direction X and are each formed in a band shape extending in the second direction Y. That is, the plurality of channel regions 26 and 27 are arranged in a stripe shape extending in the second direction Y.

The plurality of channel regions 26 and 27 include a plurality of first channel regions 26 and a plurality of second channel regions 27. The plurality of first channel regions 26 are demarcated in regions between one ends (surface layer drift region 22) of the plurality of body regions 20 and the plurality of first source regions 23, respectively, and form a current path extending in a horizontal direction. The plurality of second channel regions 27 are demarcated in regions between the other ends (surface layer drift region 22) of the plurality of body regions 20 and the plurality of second source regions 24, respectively, and form a current path extending in the horizontal direction.

The semiconductor device 1 includes a plurality of gate structures 30 of a planar electrode type disposed on the first principal surface 3 in the active region 8. The plurality of gate structures 30 are arranged at intervals in the first direction X, and each formed in a band shape extending in the second direction Y. That is, the plurality of gate structures 30 are arranged in a stripe shape extending in the second direction Y. The extension direction of the plurality of gate structures 30 coincides with the off direction of the SiC monocrystal.

Each gate structure 30 is disposed on at least one channel region 26 or 27. In this embodiment, each gate structure 30 is disposed such as to extend across two body regions 20 adjacent to each other across one surface layer drift region 22, and covers the plurality of channel regions 26 and 27. Specifically, each gate structure 30 is disposed such as to extend across the first source region 23 on one body region 20 side and the second source region 24 on the other body region 20 side, and covers the surface layer drift region 22, the first source region 23, the second source region 24, the first channel region 26, and the second channel region 27.

Hereinafter, a configuration of one gate structure 30 shall be described. The gate structure 30 has a laminated structure including an insulating film 31 and a gate electrode 32. The gate structure 30 does not have an insulating side wall structure (spacer) at a side of the gate electrode 32. The insulating film 31 may include at least one among a silicon oxide film, a silicon nitride film, and a silicon oxynitride film. In this embodiment, the insulating film 31 has a single layer structure constituted of the silicon oxide film. The insulating film 31 particularly preferably includes a silicon oxide film constituted of an oxide of the chip 2.

The insulating film 31 covers the first principal surface 3 in a film shape and is disposed on at least one channel region 26 or 27. In this embodiment, the insulating film 31 is disposed such as to extend across two body regions 20 adjacent to each other across one surface layer drift region 22, and covers the plurality of channel regions 26 and 27.

Specifically, the insulating film 31 is disposed such as to extend across the first source region 23 on one body region 20 side and the second source region 24 on the other body region 20 side, and covers the surface layer drift region 22, the first source region 23, the second source region 24, the first channel region 26, and the second channel region 27.

The insulating film 31 partially covers the first source region 23 at an interval from the contact region 25, and exposes a part of the first source region 23 and the contact region 25 from the first principal surface 3. The insulating film 31 partially covers the second source region 24 at an interval from the contact region 25, and exposes a part of the second source region 24 and the contact region 25 from the first principal surface 3.

The thickness of the insulating film 31 may be 10 nm or more and 150 nm or less. The thickness of the insulating film 31 may have a value belonging to at least one range among 10 nm or more and 25 nm or less, 25 nm or more and 50 nm or less, 50 nm or more and 75 nm or less, 75 nm or more and 100 nm or less, 100 nm or more and 125 nm or less, and 125 nm or more and 150 nm or less. The thickness of the insulating film 31 is preferably 25 nm or more and 75 nm or less.

The gate electrode 32 is disposed on the insulating film 31 and faces at least one channel region 26 or 27 across the insulating film 31. A gate potential as a control potential is applied to the gate electrode 32. The gate electrode 32 controls inversion and non-inversion of at least one channel region 26 or 27 in response to the gate potential.

The gate electrode 32 contains a semiconductor polycrystal having conductivity. The gate electrode 32 may contain either or both of a p-type conductive polysilicon and an n-type conductive polysilicon. The conductivity type of the gate electrode 32 is adjusted according to the gate threshold voltage to be achieved. The gate electrode 32 may be referred to as a “polysilicon gate,” a “poly gate,” etc.

The gate electrode 32 is formed in a band shape extending in the second direction Y. That is, the extension direction of the gate electrode 32 coincides with the off direction of the SiC monocrystal. In this embodiment, the gate electrode 32 is formed at intervals inward from both end portions of the insulating film 31 in the first direction X, and exposes both end portions of the insulating film 31. The gate electrode 32 is disposed on the insulating film 31 such as to extend across two body regions 20 adjacent to each other across one surface layer drift region 22, and faces the plurality of channel regions 26 and 27 across the insulating film 31.

Specifically, the gate electrode 32 is disposed such as to extend across the first source region 23 on one body region 20 side and the second source region 24 on the other body region 20 side, and faces the surface layer drift region 22, the first source region 23, the second source region 24, the first channel region 26, and the second channel region 27 across the insulating film 31.

The gate electrode 32 includes an electrode surface 33, a first side wall 34 on one side in the first direction X, and a second side wall 35 on the other side in the first direction X. The electrode surface 33 extends along the insulating film 31 (first principal surface 3). The electrode surface 33 may extend substantially parallel to the insulating film 31 (first principal surface 3).

The first side wall 34 is formed at an interval from one end portion toward the other end portion of the insulating film 31 in the first direction X, and extends in the vertical direction Z. The second side wall 35 is formed at an interval from the other end portion toward the one end portion of the insulating film 31 in the first direction X, and extends in the vertical direction Z.

The first side wall 34 and the second side wall 35 may extend perpendicularly to the insulating film 31. That is, the gate electrode 32 may be formed in a quadrangular shape (flat rectangular shape) in cross-sectional view. The first side wall 34 and the second side wall 35 may be inclined obliquely toward the electrode surface 33. That is, the gate electrode 32 may be formed in a tapered shape (preferably an isosceles trapezoidal shape) in cross-sectional view.

A width of the gate structure 30 may be 1 μm or more and 10 μm or less. The width of the gate structure 30 is a width in a direction orthogonal to the extension direction (that is, the first direction X). The width of the gate structure 30 is preferably 1 μm or more and 5 μm or less.

A thickness of the gate structure 30 may be 0.1 μm or more and 2.0 μm or less. The thickness of the gate structure 30 is preferably 0.2 μm or more and 1.0 μm or less.

Referring to FIGS. 4, 5, and 8, the semiconductor device 1 includes a p-type terminal region 45 formed on the first principal surface 3 in the outer peripheral region 9. The terminal region 45, which may be referred to as a “well region,” a “terminal well region,” etc., may have a p-type impurity concentration substantially equal to the p-type impurity concentration of the outer body region 21. The p-type impurity concentration of the terminal region 45 may be higher than the p-type impurity concentration of the outer body region 21, or may be lower than the p-type impurity concentration of the outer body region 21.

The terminal region 45 is formed in a region between the peripheral edges of the first principal surface 3 and the outer body region 21 at intervals inward from the peripheral edges of the first principal surface 3. The terminal region 45 extends in a band shape along the outer body region 21 in plan view. The terminal region 45 has a portion extending in a band shape in the first direction X and a portion extending in a band shape in the second direction Y in plan view, and demarcates the active region 8 from a plurality of directions.

In this embodiment, the terminal region 45 surrounds the outer body region 21 in plan view, and is demarcated in a polygonal annular shape (a quadrangular annular shape in this embodiment) having four sides parallel to the peripheral edges of the first principal surface 3. The terminal region 45 may have an edge portion connecting the portion extending in the first direction X and the portion extending in the second direction Y in plan view in an arcuate shape (preferably a quadrant arcuate shape) (see FIG. 4).

The terminal region 45 is formed at an interval from the bottom portion of the first semiconductor region 6 toward the first principal surface 3, and faces the second semiconductor region 7 across a part of the first semiconductor region 6. The terminal region 45 is preferably formed at an interval from the intermediate portion of the first semiconductor region 6 toward the first principal surface 3. The terminal region 45 may have a thickness (depth) substantially equal to the thickness (depth) of the outer body region 21. The thickness of the terminal region 45 may be larger than the thickness of the outer body region 21, or may be smaller than the thickness of the outer body region 21.

The terminal region 45 has an inner edge portion on the active region 8 side and an outer edge portion on the peripheral edge side of the first principal surface 3. The inner edge portion of the terminal region 45 is connected to the outer edge portion of the outer body region 21. As a result, the terminal region 45 is fixed at the same potential as the outer body region 21, and is electrically connected to the plurality of body regions 20 through the outer body region 21. In this embodiment, the inner edge portion of the terminal region 45 is connected to the outer edge portion of the outer body region 21 over an entire circumference.

The terminal region 45 (inner edge portion) has an overlap region 46 overlapping the outer edge portion of the outer body region 21. The overlap region 46 is a high concentration region including the outer edge portion of the outer body region 21 and the inner edge portion of the terminal region 45. That is, the overlap region 46 includes both the p-type impurity of the outer body region 21 and the p-type impurity of the terminal region 45, and has a p-type impurity concentration higher than both the p-type impurity concentration of the outer body region 21 and the p-type impurity concentration of the terminal region 45.

The overlap region 46 extends in a band shape along the outer body region 21 in plan view. The overlap region 46 has a portion extending in a band shape in the first direction X and a portion extending in a band shape in the second direction Y in plan view, and demarcates the active region 8 from a plurality of directions. In this embodiment, the overlap region 46 is demarcated in a polygonal annular shape (a quadrangular annular shape in this embodiment) having four sides parallel to the peripheral edges of the first principal surface 3. A width of the overlap region 46 is preferably larger than the width of the body region 20. As a matter of course, the width of the overlap region 46 may be not more than the width of the body region 20.

The semiconductor device 1 may have a p-type well region (46) having a relatively high concentration instead of the overlap region 46. In this case, the well region (46) has a p-type impurity concentration higher than both the p-type impurity concentration of the outer body region 21 and the p-type impurity concentration of the terminal region 45. The well region (46) may be formed in either or both of a surface layer portion of the outer body region 21 and a surface layer portion of the terminal region 45.

The semiconductor device 1 includes at least one (preferably, two or more and twenty or less) p-type field region 47 formed in the surface layer portion of the first principal surface 3 in the outer peripheral region 9. The number of the plurality of field regions 47 is typically three or more and eight or less. In this embodiment, the semiconductor device 1 includes three field regions 47. The plurality of field regions 47 are formed in an electrically floating state, and relax an electric field in the chip 2 at a peripheral edge portion of the first principal surface 3. The number, interval, width, depth, p-type impurity concentration, etc., of the field regions 47 are arbitrary, and can take various values according to the electric field to be relaxed.

The field region 47 may have a p-type impurity concentration substantially equal to the p-type impurity concentration of the body region 20 (terminal region 45). The p-type impurity concentration of the field region 47 may be higher than the p-type impurity concentration of the body region 20 (terminal region 45), or may be lower than the p-type impurity concentration of the body region 20 (terminal region 45).

The plurality of field regions 47 are formed in a region between the peripheral edges of the first principal surface 3 and the active region 8 at intervals inward from the peripheral edges of the first principal surface 3. Specifically, the plurality of field regions 47 are formed in a region between the peripheral edges of the first principal surface 3 and the outer body region 21. More specifically, in a region between the peripheral edges of the first principal surface 3 and the terminal region 45, the plurality of field regions 47 are arranged at intervals from the terminal region 45 toward the peripheral edges of the first principal surface 3.

The plurality of field regions 47 are formed in a band shape extending along the active region 8 (terminal region 45) in plan view. Each of the plurality of field regions 47 has a portion extending in a band shape in the first direction X and a portion extending in a band shape in the second direction Y. In this embodiment, the plurality of field regions 47 are formed in a polygonal annular shape (in this embodiment, a quadrangular annular shape) surrounding the active region 8 (terminal region 45) in plan view. The plurality of field regions 47 may have an edge portion connecting the portion extending in the first direction X and the portion extending in the second direction Y in an arcuate shape (preferably a quadrant arcuate shape) (see FIG. 4).

The plurality of field regions 47 are formed at intervals from the bottom portion of the first semiconductor region 6 toward the first principal surface 3, and face the second semiconductor region 7 across a part of the first semiconductor region 6. The plurality of field regions 47 are preferably formed at intervals from the intermediate portion of the first semiconductor region 6 toward the first principal surface 3.

Referring to FIG. 8, the semiconductor device 1 includes an outer peripheral insulating film 51 covering the first principal surface 3 in the outer peripheral region 9. The outer peripheral insulating film 51 may include at least one among a silicon oxide film, a silicon nitride film, and a silicon oxynitride film. In this embodiment, the outer peripheral insulating film 51 has a single layer structure constituted of the silicon oxide film. The outer peripheral insulating film 51 particularly preferably includes a silicon oxide film constituted of an oxide of the chip 2. The outer peripheral insulating film 51 is preferably made of the same kind of insulating material as the insulating material of the insulating film 31. The outer peripheral insulating film 51 preferably has a thickness substantially equal to the thickness of the insulating film 31.

The outer peripheral insulating film 51 covers the first principal surface 3 in a film shape in the outer peripheral region 9. The outer peripheral insulating film 51 collectively covers the outer body region 21, the terminal region 45, and the plurality of field regions 47. The outer peripheral insulating film 51 is connected to the plurality of insulating films 31 on the active region 8 side. Specifically, the outer peripheral insulating film 51 is integrally formed with the plurality of insulating films 31, and forms one insulating film with the plurality of insulating films 31.

Referring to FIGS. 4, 5, and 8, the semiconductor device 1 includes a gate wiring 52 disposed on the first principal surface 3 in the outer peripheral region 9. The semiconductor device 1 does not have an insulating side wall structure (spacer) at a side of the gate wiring 52. The gate wiring 52 is selectively routed on the first principal surface 3 and has a portion extending in a direction different from the plurality of gate electrodes 32. The gate wiring 52 is connected to the plurality of gate electrodes 32, and applies a gate signal to the plurality of gate electrodes 32. The gate wiring 52 may be referred to as a “polysilicon gate wiring,” a “poly gate wiring,” a “second gate electrode,” etc.

The gate wiring 52 contains a semiconductor polycrystal having conductivity. The gate wiring 52 may contain either or both of a p-type conductive polysilicon and an n-type conductive polysilicon. The gate wiring 52 preferably has the same conductivity type as the conductivity type of the gate electrode 32. The conductivity type of the gate wiring 52 is adjusted according to the conductivity type of the gate electrode 32.

The gate wiring 52 is disposed on the outer peripheral insulating film 51 in the outer peripheral region 9. Specifically, the gate wiring 52 is disposed on a portion of the outer peripheral insulating film 51 covering the outer body region 21, and faces the outer body region 21 across the outer peripheral insulating film 51. The gate wiring 52 is formed at intervals from the peripheral edges of the first principal surface 3 toward the active region 8, and extends in a band shape along the active region 8. The gate wiring 52 has a portion extending in a band shape in the first direction X and a portion extending in a band shape in the second direction Y in plan view, and demarcates the active region 8 from a plurality of directions.

In this embodiment, the gate wiring 52 surrounds the active region 8 in plan view, and is demarcated in a polygonal annular shape (a quadrangular annular shape in this embodiment) having four sides parallel to the peripheral edges of the first principal surface 3. The gate wiring 52 may have a shape with ends or an endless shape. In this embodiment, the gate wiring 52 extends in a band shape (an annular shape in this embodiment) along the outer body region 21 in plan view, and faces the outer body region 21 across the outer peripheral insulating film 51 in an entire region in the lamination direction. The gate wiring 52 may have an edge portion connecting the portion extending in the first direction X and the portion extending in the second direction Y in plan view in an arcuate shape (preferably a quadrant arcuate shape) (see FIG. 4).

The gate wiring 52 is formed to be narrower than the outer body region 21 in plan view, and is disposed above the outer body region 21 at intervals from the inner edge portion and the outer edge portion of the outer body region 21. That is, in this embodiment, the plurality of gate electrodes 32 are led out above the outer body region 21, and the gate wiring 52 is connected to the plurality of gate electrodes 32 above the outer body region 21.

A width of the gate wiring 52 is preferably larger than the width of the gate electrode 32. The width of the gate wiring 52 is a width in a direction orthogonal to the extension direction. As a matter of course, the width of the gate wiring 52 may be not more than the width of the gate electrode 32. The width of the gate wiring 52 may be larger than the width of the outer body region 21. A thickness of the gate wiring 52 is preferably substantially equal to the thickness of the gate electrode 32.

The gate wiring 52 includes a wiring surface 53, a first wiring side wall 54 on the inner edge side, and a second wiring side wall 55 on the outer edge side. The wiring surface 53 extends along the outer peripheral insulating film 51 (first principal surface 3). The wiring surface 53 may extend substantially parallel to the outer peripheral insulating film 51 (first principal surface 3). The first wiring side wall 54 extends in the vertical direction Z on the outer peripheral insulating film 51, and the second wiring side wall 55 extends in the vertical direction Z on the outer peripheral insulating film 51.

The first wiring side wall 54 is connected to the plurality of gate electrodes 32 (the first side wall 34 and the second side wall 35) in a portion extending in the first direction X. That is, the gate wiring 52 has a plurality of portions connected to the plurality of gate electrodes 32 in a T shape. Thus, the gate wiring 52 is fixed at the same potential as the plurality of gate electrodes 32.

The first wiring side wall 54 and the second wiring side wall 55 may extend perpendicularly to the outer peripheral insulating film 51. That is, the gate wiring 52 may be formed in a quadrangular shape (flat rectangular shape) in cross-sectional view. The first wiring side wall 54 and the second wiring side wall 55 may be inclined obliquely toward the wiring surface 53. That is, the gate wiring 52 may be formed in a tapered shape (preferably an isosceles trapezoidal shape) in cross-sectional view.

The semiconductor device 1 includes an insulating interlayer film 70 that covers the first principal surface 3. The interlayer film 70 may be referred to as an “interlayer insulating film,” an “intermediate insulating film,” etc. The interlayer film 70 has an insulating surface 71 extending along the first principal surface 3. The interlayer film 70 collectively covers the active region 8 and the outer peripheral region 9 on the first principal surface 3.

The interlayer film 70 covers the plurality of gate structures 30 in the active region 8. The interlayer film 70 directly covers both the insulating film 31 and the gate electrode 32 with respect to each gate structure 30. That is, the interlayer film 70 has a portion that directly covers the electrode surface 33, the first side wall 34, and the second side wall 35 of the gate electrode 32.

The interlayer film 70 collectively covers the outer body region 21, the terminal region 45, and the plurality of field regions 47 across the outer peripheral insulating film 51 in the outer peripheral region 9. The interlayer film 70 directly covers both the outer peripheral insulating film 51 and the gate wiring 52. That is, the interlayer film 70 has a portion that directly covers the wiring surface 53, the first wiring side wall 54, and the second wiring side wall 55 of the gate wiring 52. In this embodiment, the interlayer film 70 is continuous with the first to fourth side surfaces 5A to 5D. The interlayer film 70 may be formed at intervals inward from the first to fourth side surfaces 5A to 5D and expose the peripheral edge portion (first semiconductor region 6) of the first principal surface 3.

In this embodiment, the interlayer film 70 has a laminated structure including a first oxide film 72 (first insulating film) and a second oxide film 73 (second insulating film) laminated in this order from the first principal surface 3 side. That is, the interlayer film 70 has the insulating surface 71 formed by the second oxide film 73. The first oxide film 72 has a single layer structure constituted of the silicon oxide film that is not doped with an impurity. The first oxide film 72 may be referred to as an NSG film (non-doped silicate glass film).

The first oxide film 72 collectively covers the active region 8 and the outer peripheral region 9. The first oxide film 72 collectively covers the plurality of gate structures 30 in the active region 8. The first oxide film 72 covers both the insulating film 31 and the gate electrode 32 in a film shape with respect to each gate structure 30.

The first oxide film 72 includes a first covering portion 74, a second covering portion 75, and a third covering portion 76. The first covering portion 74 extends in a film shape in the horizontal direction along the insulating film 31 (first principal surface 3) and has a portion in contact with the first side wall 34 (second side wall 35) of the gate electrode 32. In this embodiment, the first covering portion 74 (first oxide film 72) has a thickness less than the thickness of the gate electrode 32, and covers the insulating film 31 at an interval from a height position of the electrode surface 33 of the gate electrode 32 toward the insulating film 31.

The second covering portion 75 is led out from the first covering portion 74 toward the electrode surface 33 in the lamination direction, and directly covers the first side wall 34 (second side wall 35) in a film shape.

The third covering portion 76 is led out from the second covering portion 75 toward the electrode surface 33, and extends in a film shape in the horizontal direction along the electrode surface 33. The third covering portion 76 directly covers an entire region of the electrode surface 33 between the first side wall 34 and the second side wall 35. The third covering portion 76 preferably forms an arcuate corner portion curved in an arcuate shape together with the second covering portion 75 in a portion covering a corner portion of the gate electrode 32. The arcuate corner portion may have a center of curvature on the gate electrode 32 side.

The first oxide film 72 collectively covers the outer body region 21, the terminal region 45, and the plurality of field regions 47 across the outer peripheral insulating film 51 in the outer peripheral region 9. The first oxide film 72 covers the gate wiring 52 in the outer peripheral region 9.

The first oxide film 72 includes a first wiring covering portion 77, a second wiring covering portion 78, and a third wiring covering portion 79. The first wiring covering portion 77 extends in a film shape in the horizontal direction along the outer peripheral insulating film 51 (first principal surface 3) and has a portion in contact with the first wiring side wall 54 (second wiring side wall 55) of the gate wiring 52. In this embodiment, the first wiring covering portion 77 (first oxide film 72) has a thickness less than the thickness of the gate wiring 52, and covers the outer peripheral insulating film 51 at an interval from a height position of the wiring surface 53 of the gate wiring 52 toward the outer peripheral insulating film 51.

The second wiring covering portion 78 is led out from the first wiring covering portion 77 toward the wiring surface 53 in the lamination direction, and directly covers the first side wall 34 (second side wall 35) in a film shape.

The third wiring covering portion 79 is led out from the second wiring covering portion 78 toward the wiring surface 53, and extends in a film shape in the horizontal direction along the wiring surface 53. The third wiring covering portion 79 directly covers an entire region of the wiring surface 53 between the first wiring side wall 54 and the second wiring side wall 55. The third wiring covering portion 79 preferably forms an arcuate corner portion curved in an arcuate shape together with the second wiring covering portion 78 in a portion covering a corner portion of the gate wiring 52. The arcuate corner portion may have a center of curvature on the gate wiring 52 side.

The second oxide film 73 may have a single layer structure constituted of a silicon oxide film containing phosphorus or a laminated structure including a silicon oxide film containing phosphorus. The silicon oxide film containing phosphorus may contain boron. The silicon oxide film containing phosphorus may be referred to as a PSG film (phosphorus silicon glass film). The silicon oxide film containing both phosphorus and boron may be referred to as a BPSG film (boron phosphorus silicon glass film).

The second oxide film 73 may have a single layer structure constituted of a PSG film or a BPSG film laminated on the first oxide film 72. The second oxide film 73 may have a laminated structure including a PSG film laminated on the first oxide film 72 and a BPSG film laminated on the PSG film. The second oxide film 73 may have a laminated structure including a BPSG film laminated on the first oxide film 72 and a PSG film laminated on the BPSG film. In this embodiment, the second oxide film 73 has a single layer structure constituted of a PSG film as an example.

The second oxide film 73 covers the first oxide film 72 in a film shape, and collectively covers the active region 8 and the outer peripheral region 9 across the first oxide film 72. The second oxide film 73 collectively covers the plurality of gate structures 30 across the first oxide film 72 in the active region 8. Specifically, the second oxide film 73 covers both the insulating film 31 and the gate electrode 32 in a film shape across the first oxide film 72.

The second oxide film 73 includes a first upper covering portion 80 and a second upper covering portion 81. The first upper covering portion 80 covers the first covering portion 74 and the second covering portion 75 of the first oxide film 72. The first upper covering portion 80 covers the insulating film 31 across the first covering portion 74 in a portion positioned on the first covering portion 74.

The first upper covering portion 80 extends in a film shape in the lamination direction along the second covering portion 75 from above the first covering portion 74, and covers the first side wall 34 (second side wall 35) of the gate structure 30 across the second covering portion 75.

The second upper covering portion 81 covers the third covering portion 76 of the first oxide film 72. The second upper covering portion 81 extends in a film shape in the horizontal direction from the first upper covering portion 80 along the third covering portion 76, and covers the electrode surface 33 of the gate structure 30 across the third covering portion 76. The second upper covering portion 81 covers the entire region of the electrode surface 33 across the third covering portion 76 between the first side wall 34 and the second side wall 35. The second upper covering portion 81 preferably forms an arcuate corner portion curved in an arcuate shape together with the first upper covering portion 80 in a portion covering the corner portion of the gate wiring 52. The arcuate corner portion may have a center of curvature on the gate wiring 52 side.

The second oxide film 73 collectively covers the outer body region 21, the terminal region 45, and the plurality of field regions 47 across the outer peripheral insulating film 51 and the first oxide film 72 in the outer peripheral region 9. The second oxide film 73 covers the gate wiring 52 across the first oxide film 72 in the outer peripheral region 9.

The second oxide film 73 includes a first upper wiring covering portion 82 and a second upper wiring covering portion 83. The first upper wiring covering portion 82 covers the first wiring covering portion 77 and the second wiring covering portion 78 of the first oxide film 72. The first upper wiring covering portion 82 covers the outer peripheral insulating film 51 across the first wiring covering portion 77 in a portion positioned on the first wiring covering portion 77.

The first upper wiring covering portion 82 extends in a film shape in the lamination direction along the second wiring covering portion 78 from above the first wiring covering portion 77, and covers the first wiring side wall 54 (second wiring side wall 55) across the second wiring covering portion 78.

The second upper wiring covering portion 83 covers the third wiring covering portion 79 of the first oxide film 72. The second upper wiring covering portion 83 extends in a film shape in the horizontal direction along the third wiring covering portion 79 from the first upper wiring covering portion 82, and covers the wiring surface 53 across the third wiring covering portion 79. The second upper wiring covering portion 83 covers the entire region of the wiring surface 53 across the third wiring covering portion 79 between the first wiring side wall 54 and the second wiring side wall 55. The second upper wiring covering portion 83 preferably forms an arcuate corner portion curved in an arcuate shape together with the first upper wiring covering portion 82 in a portion covering the corner portion of the gate wiring 52. The arcuate corner portion may have a center of curvature on the gate wiring 52 side.

The semiconductor device 1 includes a plurality of source openings 90 formed in the interlayer film 70 in the active region 8. The plurality of source openings 90 are formed in regions at sides of the plurality of gate electrodes 32 at intervals from the plurality of gate electrodes 32, respectively, and expose the first principal surface 3 (chip 2). Specifically, the plurality of source openings 90 are formed in regions between the plurality of gate electrodes 32, respectively, and penetrate through the insulating film 31 and the interlayer film 70.

The plurality of source openings 90 have wall surfaces penetrating through both the first oxide film 72 and the second oxide film 73 and demarcated by both the first oxide film 72 and the second oxide film 73. The plurality of source openings 90 have opening ends demarcated by arcuate corner portions of the interlayer film 70. The plurality of source openings 90 respectively expose the corresponding plurality of source regions 23 and 24 and the contact region 25.

In this embodiment, the plurality of source openings 90 are formed at intervals in the first direction X, and are each formed in a band shape extending in the second direction Y. That is, the plurality of source openings 90 are formed in a stripe shape extending in the second direction Y. The plurality of source openings 90 are formed at intervals in the second direction Y from the gate wiring 52. That is, the plurality of source openings 90 are formed in a region surrounded by the plurality of gate electrodes 32 and the gate wiring 52.

The plurality of source openings 90 may be formed in a region between two gate structures 30 adjacent to each other in the first direction X. In this case, the plurality of source openings 90 may be formed at intervals in a line in the second direction Y. Furthermore, in this case, each source opening 90 may be formed in a quadrangular shape (square shape), a rectangular shape extending in the first direction X, a rectangular shape extending in the second direction Y, a hexagonal shape, a circular shape, etc., in plan view.

The source opening 90 may have a width W of 0.2 μm or more and 3 μm or less. The width W of the source opening 90 is preferably 0.3 μm or more and 1 μm or less. The source opening 90 may have a depth D of 0.2 μm or more and 2 μm or less. The depth D of the source opening 90 is preferably 0.5 μm or more and 1 μm or less.

The source opening 90 preferably has an aspect ratio D/W of 0.3 or more and 3 or less. The aspect ratio D/W is defined by the ratio of the depth D of the source opening 90 with respect to the width W of the source opening 90. The aspect ratio D/W is preferably 0.5 or more and 2 or less. The aspect ratio D/W is particularly preferably more than 1. According to this configuration, the plurality of gate structures 30 are arranged at a narrow pitch.

The semiconductor device 1 includes at least one (in this embodiment, a plurality of) outer opening 92 formed in the interlayer film 70 in the outer peripheral region 9. The plurality of outer openings 92 are formed in a portion of the interlayer film 70 covering the terminal region 45. The plurality of outer openings 92 penetrate through the interlayer film 70 and expose the terminal region 45. In this embodiment, the plurality of outer openings 92 are formed in a portion of the interlayer film 70 covering the overlap region 46 of the terminal region 45 and expose the overlap region 46.

The plurality of outer openings 92 may expose the outer body region 21 instead of or in addition to the terminal region 45 (overlap region 46). The plurality of outer openings 92 have wall surfaces penetrating through both the first oxide film 72 and the second oxide film 73 and demarcated by both the first oxide film 72 and the second oxide film 73. The plurality of outer openings 92 have opening ends demarcated by the arcuate corner portions of the interlayer film 70.

The plurality of outer openings 92 are formed at intervals along the terminal region 45 (overlap region 46) (see FIGS. 4 and 5). The plurality of outer openings 92 may be formed in a quadrangular shape (square shape), a rectangular shape, a hexagonal shape, a circular shape, etc., in plan view. The plurality of outer openings 92 may be formed in a band shape extending along the terminal region 45 (overlap region 46) in plan view. Similarly to the source opening 90, the outer opening 92 may have an aspect ratio D/W (preferably more than 1).

The semiconductor device 1 may have a single outer opening 92. The single outer opening 92 may be formed in a band shape extending along the terminal region 45 (overlap region 46). The single outer opening 92 may have a portion extending in a band shape in the first direction X and a portion extending in a band shape in the second direction Y in plan view.

The single outer opening 92 may be formed in a polygonal annular shape (a quadrangular annular shape in this embodiment) with or without ends having four sides parallel to the peripheral edges of the first principal surface 3. The single outer opening 92 may have an edge portion connecting the portion extending in the first direction X and the portion extending in the second direction Y in conformance to the terminal region 45 (overlap region 46) in plan view in an arcuate shape (preferably a quadrant arcuate shape) (see FIG. 4).

The semiconductor device 1 includes a plurality of outer recesses 93 formed in portions of the first principal surface 3 exposed from the plurality of outer openings 92, respectively. The semiconductor device 1 does not necessarily have to include the outer recess 93. Therefore, a configuration without the outer recess 93 may be adopted.

Each of the plurality of outer recesses 93 has a planar shape matching the planar shape of the corresponding outer opening 92, and is recessed from the first principal surface 3 toward the second principal surface 4. The plurality of outer recesses 93 are formed at intervals from a bottom portion of the terminal region 45 (overlap region 46) toward the first principal surface 3 and expose the terminal region 45 (overlap region 46), respectively. When the single outer opening 92 is formed, a single outer recess 93 matching the planar shape of the single outer opening 92 is formed.

The semiconductor device 1 includes at least one (in this embodiment, a plurality of) gate opening 94 formed in the interlayer film 70 in the outer peripheral region 9. The plurality of gate openings 94 are formed in a portion of the interlayer film 70 covering the gate wiring 52. The plurality of gate openings 94 penetrate through the interlayer film 70 and expose the wiring surface 53 of the gate wiring 52.

The plurality of gate openings 94 have wall surfaces penetrating through both the first oxide film 72 and the second oxide film 73 and demarcated by both the first oxide film 72 and the second oxide film 73. The plurality of gate openings 94 have opening ends demarcated by the arcuate corner portions of the interlayer film 70.

The plurality of gate openings 94 are formed at intervals along the gate wiring 52 (see FIGS. 4 and 5). The plurality of gate openings 94 may be formed in a quadrangular shape (square shape), a rectangular shape, a hexagonal shape, a circular shape, etc., in plan view. The plurality of gate openings 94 may be formed in a band shape extending along the gate wiring 52 in plan view. Similarly to the source opening 90, the gate opening 94 may have an aspect ratio D/W (preferably, more than 1).

The semiconductor device 1 may have a single gate opening 94. The single gate opening 94 may be formed in a band shape extending along the gate wiring 52. The single gate opening 94 may have a portion extending in a band shape in the first direction X and a portion extending in a band shape in the second direction Y in plan view.

The single gate opening 94 may be formed in a polygonal annular shape (a quadrangular annular shape in this embodiment) with or without ends having four sides parallel to the peripheral edges of the first principal surface 3. The single gate opening 94 may have an edge portion connecting the portion extending in the first direction X and the portion extending in the second direction Y in conformance to the gate wiring 52 in plan view in an arcuate shape (preferably a quadrant arcuate shape) (see FIG. 4).

Referring to FIG. 1, etc., the semiconductor device 1 includes a source pad electrode 95 disposed on the interlayer film 70. The source pad electrode 95 is a terminal electrode to which a source potential is externally applied. The source pad electrode 95 may be referred to as a “first pad electrode,” a “first principal surface electrode,” a “first terminal electrode,” etc.

The source pad electrode 95 is disposed on a portion of the interlayer film 70 covering the active region 8. The source pad electrode 95 covers the plurality of gate electrodes 32 across the interlayer film 70, and is electrically separated from the plurality of gate electrodes 32 by the interlayer film 70. The source pad electrode 95 is electrically connected to the plurality of body regions 20, the outer body region 21, the plurality of source regions 23 and 24, the contact region 25, etc., through the plurality of source openings 90.

In this embodiment, the source pad electrode 95 includes a first pad portion 96, a second pad portion 97, and a third pad portion 98. The first pad portion 96 has a relatively large plane area, and forms a main body of the source pad electrode 95. In this embodiment, the first pad portion 96 is formed in a polygonal shape (a quadrangular shape in this embodiment) having four sides parallel to the peripheral edges of the chip 2 in plan view, and is shifted further to the fourth side surface 5D side with respect to a central portion of the active region 8. The first pad portion 96 covers the plurality of gate electrodes 32 across the interlayer film 70, and is electrically connected to the plurality of body regions 20, etc., through the plurality of source openings 90.

The second pad portion 97 has a plane area less than the plane area of the first pad portion 96, and is led out in a band shape (quadrangular shape) from one end portion (end portion on the first side surface 5A side) of the first pad portion 96 in the second direction Y toward the third side surface 5C. The second pad portion 97 covers the plurality of gate electrodes 32 across the interlayer film 70, and is electrically connected to the plurality of body regions 20, etc., through the plurality of source openings 90.

The third pad portion 98 has a plane area less than the plane area of the first pad portion 96, is led out in a band shape (quadrangular shape) from the other end portion (end portion on the second side surface 5B side) of the first pad portion 96 in the second direction Y toward the third side surface 5C, and faces the second pad portion 97 in the second direction Y. The third pad portion 98 covers the plurality of gate electrodes 32 across the interlayer film 70, and is electrically connected to the plurality of body regions 20, etc., through the plurality of source openings 90.

The plane area of the third pad portion 98 may be substantially equal to the plane area of the second pad portion 97. As a matter of course, the plane area of the third pad portion 98 may be larger than the plane area of the second pad portion 97, or may be less than the plane area of the second pad portion 97. Either or both of the second pad portion 97 and the third pad portion 98 may be used as a terminal portion for current monitoring.

The source pad electrode 95 does not necessarily have to include both the second pad portion 97 and the third pad portion 98 at the same time. The source pad electrode 95 may include only one of the second pad portion 97 and the third pad portion 98. As a matter of course, the source pad electrode 95 may be constituted of only the first pad portion 96, and does not have to include the second pad portion 97 and the third pad portion 98.

Referring to FIGS. 6 and 7, the source pad electrode 95 includes a first base electrode film 100 and a first principal electrode film 102. The first base electrode film 100 may be referred to as a “source base electrode film,” and the first principal electrode film 102 may be referred to as a “source principal electrode film.”

The first base electrode film 100 forms a lower layer portion of the source pad electrode 95 (the first pad portion 96, the second pad portion 97, and the third pad portion 98), and covers the interlayer film 70 in the active region 8. The first base electrode film 100 collectively covers a region of the interlayer film 70 where the plurality of source openings 90 are formed in a film shape. That is, the first base electrode film 100 enters into the plurality of source openings 90 from above the insulating surface 71.

The first base electrode film 100 has a portion covering the insulating surface 71 of the interlayer film 70 in a film shape and a portion covering the wall surfaces of the plurality of source openings 90 in a film shape. The first base electrode film 100 demarcates recesses in the plurality of source openings 90, respectively. The first base electrode film 100 may have a portion partially covering the gate wiring 52 across the interlayer film 70. The first base electrode film 100 may be formed at an interval inward from the gate wiring 52 in plan view.

In this embodiment, the first base electrode film 100 has a laminated structure including a first electrode film 103 laminated on the interlayer film 70 and a second electrode film 104 laminated on the first electrode film 103. In this embodiment, the first electrode film 103 includes a Ti film, and the second electrode film 104 includes a TiN film.

The first base electrode film 100 does not necessarily have to have a laminated structure, and may have a single layer structure constituted of one of the first electrode film 103 (Ti film) and the second electrode film 104 (TiN film). A thickness of the first electrode film 103 may be 10 nm or more and 100 nm or less. A thickness of the second electrode film 104 may be 50 nm or more and 200 nm or less.

The first electrode film 103 collectively covers the region of the interlayer film 70 where the plurality of source openings 90 are formed in a film shape, and enters into the plurality of source openings 90 from above the insulating surface 71. The first electrode film 103 has a portion covering the insulating surface 71 of the interlayer film 70 in a film shape and a portion covering the wall surfaces of the plurality of source openings 90 in a film shape. The first electrode film 103 directly covers the insulating surface 71.

That is, the first electrode film 103 directly covers the second oxide film 73 on the insulating surface 71. The first oxide film 72 faces the plurality of gate electrodes 32 across the interlayer film 70 in a portion covering the insulating surface 71.

The first electrode film 103 covers the arcuate corner portion of the interlayer film 70 (second oxide film 73) in a film shape in conformance to such arcuate corner portion, and enters into the source opening 90. That is, the first electrode film 103 has a portion extending in an arcuate shape at the arcuate corner portion. Thus, the film formability of the first electrode film 103 with respect to the interlayer film 70 (the wall surface of the source opening 90) is improved.

The first electrode film 103 extends along the wall surface of the source opening 90 and covers the insulating film 31, the first oxide film 72, and the second oxide film 73. The first electrode film 103 faces the first side wall 34 (second side wall 35) of the gate electrode 32 across the interlayer film 70.

The first electrode film 103 covers the first principal surface 3 in a film shape at a bottom portion of each source opening 90, and is electrically connected to the first principal surface 3. Specifically, the first electrode film 103 has a portion covering the bottom portion of each source opening 90 in a film shape, and is electrically connected to the plurality of source regions 23 and 24 and the contact region 25.

The second electrode film 104 collectively covers the region of the interlayer film 70 where the plurality of source openings 90 are formed in a film shape on the first electrode film 103. The second electrode film 104 has a portion covering the insulating surface 71 of the interlayer film 70 in a film shape across the first electrode film 103, and a portion covering the wall surfaces of the plurality of source openings 90 in a film shape across the first electrode film 103.

The second electrode film 104 faces the plurality of gate electrodes 32 across the first electrode film 103 and the interlayer film 70 in a portion covering the insulating surface 71.

The second electrode film 104 covers the arcuate corner portion of the interlayer film 70 (second oxide film 73) in a film shape in conformance to the first electrode film 103, and enters into the source opening 90. That is, the second electrode film 104 has a portion extending in an arcuate shape at the arcuate corner portion of the interlayer film 70. Thus, the film formability of the second electrode film 104 with respect to the interlayer film 70 (the wall surface of the source opening 90) is improved.

The second electrode film 104 extends along the wall surface of the source opening 90, and covers the insulating film 31, the first oxide film 72, and the second oxide film 73 across the first electrode film 103. The second electrode film 104 faces the first side wall 34 (second side wall 35) of the gate electrode 32 across the first electrode film 103 and the interlayer film 70.

The second electrode film 104 has a portion covering the bottom portion of each source opening 90 in a film shape across the first electrode film 103, and is electrically connected to the plurality of source regions 23 and 24 and the contact region 25 through the first electrode film 103.

The first principal electrode film 102 forms an upper layer portion of the source pad electrode 95 (the first pad portion 96, the second pad portion 97, and the third pad portion 98) and covers the first base electrode film 100 in a film shape. The first principal electrode film 102 contains a conductive material different from the conductive material of the first base electrode film 100.

The first principal electrode film 102 may include at least one among an Al film, an Al alloy film, a Cu film, and a Cu alloy film. The Al alloy film may include at least one among an AlSi alloy film, an AlCu alloy film, and an AlSiCu alloy film. The first principal electrode film 102 has a thickness larger than the thickness (total thickness) of the first base electrode film 100.

The thickness of the first principal electrode film 102 may be 0.5 μm or more and 5 μm or less. The thickness of the first principal electrode film 102 may have a value belonging to at least one range among 0.5 μm or more and 1 μm or less, 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less.

The first principal electrode film 102 is mechanically and electrically connected to the first base electrode film 100 in a portion covering the insulating surface 71. As a result, the first principal electrode film 102 faces the plurality of gate electrodes 32 across the first base electrode film 100 and the interlayer film 70.

The semiconductor device 1 includes a source finger electrode 110 led out from the source pad electrode 95 onto the outer peripheral region 9. The source finger electrode 110 transmits the source potential applied to the source pad electrode 95 to the outer peripheral region 9. In this embodiment, the source finger electrode 110 is routed from a portion of the source pad electrode 95 (first pad portion 96) on the fourth side surface 5D side onto a portion of the interlayer film 70 covering the outer peripheral region 9.

The source finger electrode 110 is led out above the terminal region 45, and is electrically connected to the terminal region 45 through the plurality of outer openings 92. Specifically, the source finger electrode 110 is electrically connected to the overlap region 46 of the terminal region 45 through the plurality of outer openings 92.

The source finger electrode 110 extends in a band shape along the terminal region 45 (overlap region 46). The source finger electrode 110 has a portion extending in a band shape in the first direction X and a portion extending in a band shape in the second direction Y in plan view.

In this embodiment, the source finger electrode 110 is formed in a polygonal annular shape (in this embodiment, a quadrangular annular shape) having four sides parallel to the peripheral edges of the first principal surface 3, and surrounds the source pad electrode 95. The source finger electrode 110 may have an edge portion connecting the portion extending in the first direction X and the portion extending in the second direction Y in plan view in an arcuate shape (preferably a quadrant arcuate shape) (see FIG. 4).

Similarly to the source pad electrode 95, the source finger electrode 110 includes the first base electrode film 100 and the first principal electrode film 102. The first base electrode film 100 forms a lower layer portion of the source finger electrode 110, and covers the interlayer film 70 in the outer peripheral region 9.

The first base electrode film 100 collectively covers a region of the interlayer film 70 where the plurality of outer openings 92 are formed in a film shape. That is, the first base electrode film 100 enters into the plurality of outer openings 92 from above the insulating surface 71. The first base electrode film 100 has a portion covering the insulating surface 71 of the interlayer film 70 in a film shape and a portion covering the wall surfaces of the plurality of outer openings 92 in a film shape. The first base electrode film 100 demarcates recesses in the plurality of outer openings 92, respectively.

Similarly to the source pad electrode 95, the first base electrode film 100 has a laminated structure including the first electrode film 103 and the second electrode film 104. The first electrode film 103 collectively covers the region of the interlayer film 70 where the plurality of outer openings 92 are formed in a film shape, and enters into the plurality of outer openings 92 from above the insulating surface 71. That is, the first electrode film 103 has a portion covering the insulating surface 71 of the interlayer film 70 in a film shape and a portion covering the wall surfaces of the plurality of outer openings 92 in a film shape.

The first electrode film 103 covers the arcuate corner portion of the interlayer film 70 (second oxide film 73) in a film shape in conformance to such arcuate corner portion, and enters into the outer opening 92. That is, the first electrode film 103 has a portion extending in an arcuate shape at the arcuate corner portion. Thus, the film formability of the first electrode film 103 with respect to the interlayer film 70 (the wall surface of the outer opening 92) is improved. The first electrode film 103 extends along the wall surface of the outer opening 92 and covers the outer peripheral insulating film 51, the first oxide film 72, and the second oxide film 73.

The first electrode film 103 covers the first principal surface 3 in a film shape at a bottom portion of each outer opening 92, and is electrically connected to the first principal surface 3 (chip 2). Specifically, the first electrode film 103 has a portion covering the outer recess 93 in a film shape at the bottom portion of each outer opening 92, and is electrically connected to the terminal region 45 (overlap region 46) in the outer recess 93.

The first electrode film 103 may cover the outer recess 93 in a film shape at an interval from a height position of the first principal surface 3 toward a bottom portion of the outer recess 93. The first electrode film 103 may have a portion positioned on the bottom portion side of the outer recess 93 with respect to the height position of the first principal surface 3, and a portion positioned on the outer peripheral insulating film 51 side with respect to the height position of the first principal surface 3.

The second electrode film 104 collectively covers the region of the interlayer film 70 where the plurality of outer openings 92 are formed in a film shape on the first electrode film 103.

That is, the second electrode film 104 has a portion covering the insulating surface 71 of the interlayer film 70 in a film shape across the first electrode film 103, and a portion covering the wall surfaces of the plurality of outer openings 92 in a film shape across the first electrode film 103.

The second electrode film 104 covers the arcuate corner portion of the interlayer film 70 (second oxide film 73) in a film shape in conformance to the first electrode film 103, and enters into the outer opening 92. That is, the second electrode film 104 has a portion extending in an arcuate shape at the arcuate corner portion of the interlayer film 70 (second oxide film 73). Thus, the film formability of the second electrode film 104 with respect to the interlayer film 70 (the wall surface of the outer opening 92) is improved. The second electrode film 104 extends along the wall surface of the outer opening 92, and covers the outer peripheral insulating film 51, the first oxide film 72, and the second oxide film 73 across the first electrode film 103.

The second electrode film 104 has a portion covering the outer recess 93 in a film shape across the first electrode film 103 at the bottom portion of each outer opening 92, and is electrically connected to the terminal region 45 (overlap region 46) through the first electrode film 103. When the first electrode film 103 is positioned on the bottom portion side of the outer recess 93 with respect to the first principal surface 3, the second electrode film 104 may have a portion positioned in the outer recess 93. When the first electrode film 103 has a portion positioned above the first principal surface 3, the entire second electrode film 104 is positioned above the outer recess 93.

The first principal electrode film 102 forms an upper layer portion of the source finger electrode 110 and covers the first base electrode film 100 in a film shape. The first principal electrode film 102 is mechanically and electrically connected to the first base electrode film 100 in a portion covering the insulating surface 71. That is, the first principal electrode film 102 is electrically connected to the terminal region 45 (overlap region 46) through the first base electrode film 100.

The semiconductor device 1 includes a gate finger electrode 115 selectively routed on the interlayer film 70. The gate finger electrode 115 transmits a gate potential to the gate wiring 52. The gate finger electrode 115 is routed on a portion of the interlayer film 70 covering the gate wiring 52 (that is, on the outer peripheral region 9), and is electrically connected to the gate wiring 52 through the plurality of gate openings 94.

The gate finger electrode 115 is disposed in a region between the source pad electrode 95 and the source finger electrode 110 at an interval from the source pad electrode 95 and the source finger electrode 110. The gate finger electrode 115 is disposed on the gate wiring 52 and extends in a band shape along the gate wiring 52. The gate finger electrode 115 has a portion extending in a band shape in the first direction X and a portion extending in a band shape in the second direction Y in plan view.

In this embodiment, the gate finger electrode 115 is formed in a band shape with ends having four sides parallel to the peripheral edges of the first principal surface 3, and surrounds the source pad electrode 95. The gate finger electrode 115 may have an edge portion connecting the portion extending in the first direction X and the portion extending in the second direction Y in plan view in an arcuate shape (preferably a quadrant arcuate shape) (see FIG. 4). The gate finger electrode 115 has a pair of open ends that allow the source finger electrode 110 to pass therethrough on the fourth side surface 5D side.

Referring to FIG. 9, the gate finger electrode 115 includes a second base electrode film 120 and a second principal electrode film 122. The second base electrode film 120 may be referred to as a “gate base electrode film,” and the second principal electrode film 122 may be referred to as a “gate principal electrode film.”

The second base electrode film 120 forms a lower layer portion of the gate finger electrode 115 and covers the interlayer film 70 in the outer peripheral region 9. The second base electrode film 120 collectively covers a region of the interlayer film 70 where the plurality of gate openings 94 are formed in a film shape. That is, the second base electrode film 120 enters into the plurality of gate openings 94 from above the insulating surface 71. The second base electrode film 120 has a portion covering the insulating surface 71 of the interlayer film 70 in a film shape and a portion covering the wall surfaces of the plurality of gate openings 94 in a film shape. The second base electrode film 120 demarcates a plurality of recesses in the plurality of gate openings 94, respectively.

The second base electrode film 120 has a laminated structure including a first electrode film 123 laminated on the interlayer film 70 and a second electrode film 124 laminated on the first electrode film 123. Preferably, the first electrode film 123 contains the same type of conductive material as the first electrode film 103 on the source side, and the second electrode film 124 contains the same type of conductive material as the second electrode film 104 on the source side. In this embodiment, the first electrode film 123 includes a Ti film, and the second electrode film 124 includes a TiN film.

The second base electrode film 120 does not necessarily have to have a laminated structure, and may have a single layer structure constituted of one of the first electrode film 123 (Ti film) and the second electrode film 124 (TiN film). The first electrode film 123 may have a thickness substantially equal to the thickness of the first electrode film 103 on the source side. The second electrode film 124 may have a thickness substantially equal to the thickness of the second electrode film 104 on the source side.

The first electrode film 123 collectively covers the region of the interlayer film 70 where the plurality of gate openings 94 are formed in a film shape, and enters into the plurality of gate openings 94 from above the insulating surface 71. That is, the first electrode film 123 has a portion covering the insulating surface 71 of the interlayer film 70 in a film shape and a portion covering the wall surfaces of the plurality of gate openings 94 in a film shape.

The first electrode film 123 covers the arcuate corner portion of the interlayer film 70 (second oxide film 73) in a film shape in conformance to such arcuate corner portion, and enters into the gate opening 94. That is, the first electrode film 123 has a portion extending in an arcuate shape at the arcuate corner portion. Thus, the film formability of the first electrode film 123 with respect to the interlayer film 70 (the wall surface of the gate opening 94) is improved. The first electrode film 123 extends along the wall surface of the gate opening 94 and covers the outer peripheral insulating film 51, the first oxide film 72, and the second oxide film 73.

The first electrode film 123 covers the gate wiring 52 in a film shape at a bottom portion of each gate opening 94, and is electrically connected to the gate wiring 52.

The second electrode film 124 collectively covers the region of the interlayer film 70 where the plurality of gate openings 94 are formed in a film shape on the first electrode film 123. That is, the second electrode film 124 has a portion covering the insulating surface 71 of the interlayer film 70 in a film shape across the first electrode film 123, and a portion covering the wall surfaces of the plurality of gate openings 94 in a film shape across the first electrode film 123.

The second electrode film 124 covers the arcuate corner portion of the interlayer film 70 (second oxide film 73) in a film shape in conformance to the first electrode film 123, and enters into the gate opening 94. That is, the second electrode film 124 has a portion extending in an arcuate shape at the arcuate corner portion of the interlayer film 70 (second oxide film 73). Thus, the film formability of the second electrode film 124 with respect to the interlayer film 70 (the wall surface of the gate opening 94) is improved. The second electrode film 124 extends along the wall surface of the gate opening 94, and covers the outer peripheral insulating film 51, the first oxide film 72, and the second oxide film 73 across the first electrode film 123.

The second electrode film 124 has a portion covering the gate wiring 52 in a film shape across the first electrode film 123 at the bottom portion of each gate opening 94, and is electrically connected to the gate wiring 52 through the first electrode film 123.

The second principal electrode film 122 forms an upper layer portion of the gate finger electrode 115 and covers the second base electrode film 120 in a film shape. The second principal electrode film 122 contains a conductive material different from the conductive material of the second base electrode film 120.

The second principal electrode film 122 may include at least one among an Al film, an Al alloy film, a Cu film, and a Cu alloy film. The Al alloy film may include at least one among an AlSi alloy film, an AlCu alloy film, and an AlSiCu alloy film. The second principal electrode film 122 preferably contains the same type of conductive material as the conductive material of the first principal electrode film 102. The second principal electrode film 122 may have a thickness substantially equal to the thickness of the first principal electrode film 102.

The second principal electrode film 122 is mechanically and electrically connected to the second base electrode film 120 in a portion covering the insulating surface 71.

The semiconductor device 1 includes a gate pad electrode 130 disposed on the interlayer film 70. The gate pad electrode 130 is a terminal electrode to which a gate potential is externally applied. The gate pad electrode 130 may be referred to as a “second pad electrode,” a “second principal surface electrode,” a “second terminal electrode,” etc. The gate pad electrode 130 is disposed in a region between the source pad electrode 95 and the source finger electrode 110 at an interval from the source pad electrode 95 and the source finger electrode 110.

In this embodiment, the gate pad electrode 130 is disposed in a region on the third side surface 5C side with respect to the first pad portion 96, and is sandwiched between the second pad portion 97 and the third pad portion 98. That is, the gate pad electrode 130 faces the first pad portion 96 in the first direction X, and faces the second pad portion 97 and the third pad portion 98 in the second direction Y.

The gate pad electrode 130 is formed in a polygonal shape (a quadrangular shape in this embodiment) having four sides parallel to the peripheral edges of the chip 2 in plan view. The gate pad electrode 130 has a plane area less than a plane area of the source pad electrode 95 (first pad portion 96). The gate pad electrode 130 may have a plane area less than the plane area of the second pad portion 97 (third pad portion 98).

The gate pad electrode 130 is disposed on a portion covering the active region 8 and the outer peripheral region 9, and is connected to the gate finger electrode 115. The gate pad electrode 130 may cover the plurality of gate electrodes 32 across the interlayer film 70, or may cover the gate wiring 52 across the interlayer film 70.

Similarly to the gate finger electrode 115, the gate pad electrode 130 includes the second base electrode film 120 and the second principal electrode film 122. The second base electrode film 120 forms a lower layer portion of the gate pad electrode 130 and covers the interlayer film 70 in a film shape. Similarly to the gate finger electrode 115, the second base electrode film 120 has a laminated structure including the first electrode film 123 and the second electrode film 124.

The first electrode film 123 covers the interlayer film 70 in a film shape, and the second electrode film 124 covers the first electrode film 123 in a film shape. The second principal electrode film 122 forms an upper layer portion of the gate pad electrode 130 and covers the second base electrode film 120 in a film shape.

The gate potential applied to the gate pad electrode 130 is applied to the gate wiring 52 through the gate finger electrode 115. The gate potential is transmitted to the plurality of gate electrodes 32 through a wiring path (current path) along the gate wiring 52. As a result, the plurality of gate electrodes 32 are turned on, and on/off of the plurality of channel regions 26 and 27 is controlled.

The semiconductor device 1 includes a drain pad electrode 140 covering the second principal surface 4. The drain pad electrode 140 is a terminal electrode to which a drain potential is externally applied. The drain pad electrode 140 may be referred to as a “third pad electrode,” a “third principal surface electrode,” a “third terminal electrode,” etc. The drain pad electrode 140 is electrically connected to the second semiconductor region 7. The drain pad electrode 140 may cover an entire region of the second principal surface 4 such as to be continuous with the peripheral edges (the first to fourth side surfaces 5A to 5D) of the second principal surface 4. The drain pad electrode 140 may partially cover the second principal surface 4 such as to expose a peripheral edge portion of the second principal surface 4.

A breakdown voltage that can be applied between the source pad electrode 95 and the drain pad electrode 140 (between the first principal surface 3 and the second principal surface 4) may be 500 V or more and 3000 V or less. The breakdown voltage may have a value belonging to at least one range among 500 V or more and 1000 V or less, 1000 V or more and 1500 V or less, 1500 V or more and 2000 V or less, 2000 V or more and 2500 V or less, and 2500 V or more and 3000 V or less.

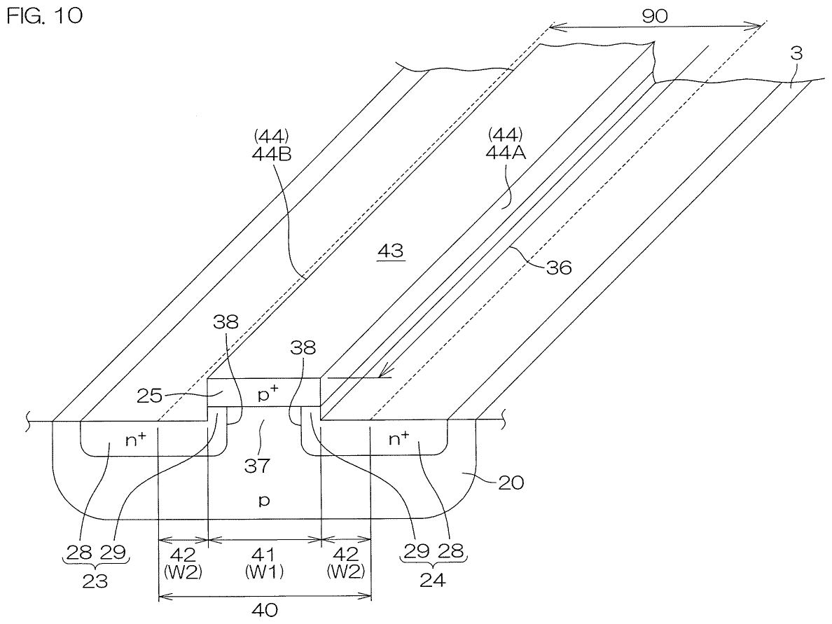

Next, a contact structure for the source regions 23 and 24 will be described in detail with reference to FIGS. 6, 7, and 10. FIG. 10 is a schematic perspective view illustrating a structure of a mesa contact portion 41 in detail.

In the semiconductor device 1, a part of the chip 2 is exposed as a contact portion 40 from the source opening 90 between the adjacent gate structures 30. The source pad electrode 95 is mechanically and electrically connected to the contact portion 40 in the source opening 90.

Referring to FIGS. 7 and 10, in this embodiment, the contact portion 40 includes the mesa contact portion 41 and a flat contact portion 42.

The mesa contact portion 41 is formed such as to be separated inward from both side walls of the source opening 90. The mesa contact portion 41 extends in a band shape along a stripe direction of the gate structure 30. In this embodiment, one mesa contact portion 41 is formed in each source opening 90 extending in a band shape, and a plurality of mesa contact portions 41 are arranged in a stripe shape as a whole.

Each mesa contact portion 41 protrudes from the first principal surface 3 and has a mesa upper portion 43 and a mesa side portion 44.

The mesa upper portion 43 may extend substantially parallel to the insulating film 31 (first principal surface 3). The mesa upper portion 43 may be referred to as a mesa upper wall.

The mesa side portion 44 may include a first mesa side portion 44A facing the first side wall 34 and a second mesa side portion 44B facing the second side wall 35. Both the first mesa side portion 44A and the second mesa side portion 44B are formed at an interval from the side wall of the interlayer film 70 in the first direction X, and extend in the vertical direction Z. The first mesa side portion 44A and the second mesa side portion 44B may extend perpendicularly to the first principal surface 3. That is, the mesa contact portion 41 may be formed in a quadrangular shape (flat rectangular shape) in cross-sectional view.

Although not illustrated, the first mesa side portion 44A and the second mesa side portion 44B may be inclined obliquely toward the mesa upper portion 43. That is, the mesa contact portion 41 may be formed in a tapered shape (preferably an isosceles trapezoidal shape) in cross-sectional view. The first mesa side portion 44A and the second mesa side portion 44B may be referred to as a first mesa side wall and a second mesa side wall, respectively.

The flat contact portion 42 is a region formed by a part of the first principal surface 3 between the mesa contact portion 41 and the side wall of the source opening 90. In this embodiment, a pair of flat contact portions 42 sandwiching the band-shaped mesa contact portion 41 are formed in a stripe shape side by side with the mesa contact portion 41.

A width W1 of the mesa contact portion 41 may be wider than a width W2 of each flat contact portion 42. The width W1 of the mesa contact portion 41 may be wider than the total of W2 of the pair of flat contact portions 42. The width W1 of the mesa contact portion 41 may be wider than ½ of the width W of the source opening 90.

In this embodiment, the mesa contact portion 41 is formed by the body region 20, the contact region 25, and the source regions 23 and 24. The mesa contact portion 41 includes these three impurity regions as a result of the body region 20, the contact region 25, and the source regions 23 and 24 being demarcated in a predetermined pattern in cross-sectional view.

At least one of the contact region 25 and the source regions 23 and 24 is exposed from the mesa upper portion 43 and the mesa side portion 44 of the mesa contact portion 41 and is connected to the source pad electrode 95.

In this embodiment, the mesa contact portion 41 includes an impurity region in the form of a first contact portion 36. Referring to FIG. 10, the mesa contact portion 41 includes, at the first contact portion 36, a body protrusion portion 37 formed by a part of the body region 20 and passing through sides of the source regions 23 and 24 toward the mesa upper portion 43, the contact region 25 connected to the body protrusion portion 37 at the mesa upper portion 43, and the source regions 23 and 24 formed around the body protrusion portion 37 and exposed from the mesa side portion 44.

The body protrusion portion 37 has a boundary surface 38 with the source regions 23 and 24 at a position at an interval inward from each of the first mesa side portion 44A and the second mesa side portion 44B. As a result, the body protrusion portion 37 extends in a band shape along the band-shaped mesa contact portion 41. An upper end of the body protrusion portion 37 (a boundary with the contact region 25) may be less than ½ of a height of the mesa contact portion 41. As a matter of course, the upper end of the body protrusion portion 37 may be ½ or more of the height of the mesa contact portion 41.

The contact region 25 is continuously formed in the mesa upper portion 43 along a length direction of the mesa contact portion 41, and is exposed from three directions of the mesa upper portion 43 and a pair of mesa side portions 44A and 44B. Therefore, the contact region 25 is exposed from an entire upper surface of the mesa contact portion 41.

The first source region 23 and the second source region 24 extend between the mesa contact portion 41 and the gate electrode 32, and have end portions on the inner side in a width direction of the mesa contact portion 41. Each of the source regions 23 and 24 integrally includes a source flat portion 28 exposed from the flat contact portion 42 and protruding from the flat contact portion 42 to the inside of the mesa contact portion 41, and a source vertical portion 29 rising from the source flat portion 28 along the mesa side portion 44 and exposed from the mesa side portion 44. Thus, the source regions 23 and 24 are formed in a substantially L shape in cross-sectional view. The source vertical portion 29 of the first source region 23 and the source vertical portion 29 of the second source region 24 face each other at an interval in the first direction X inside the mesa contact portion 41, and the body protrusion portion 37 is formed therebetween.

In this embodiment, the first source region 23 and the second source region 24 are integrally exposed from the lower side of the mesa contact portion 41 and the flat contact portion 42 along the stripe direction of the mesa contact portion 41.

Referring to FIG. 7, the source pad electrode 95 enters into the contact portion 40 and covers the mesa upper portion 43 and the mesa side portion 44. The source pad electrode 95 is mechanically and electrically connected to the contact region 25 on the upper side of the mesa upper portion 43 and the mesa side portion 44, and is mechanically and electrically connected to the source regions 23 and 24 on the lower side of the mesa side portion 44 and the flat contact portion 42. In this embodiment, the first base electrode film 100 is embedded in a gap 39 between the mesa contact portion 41 and the interlayer film 70, and the first principal electrode film 102 is embedded in a region above the mesa contact portion 41 of the source opening 90.

For example, the plurality of gate structures 30 may be arranged at a narrow pitch in order to meet a demand for size reduction of a device. Since a distance between the adjacent gate structures 30 is narrowed, the width W of the source opening 90 for the source contact becomes very small. Reducing the width W of the source opening 90 reduces a contact area of the source pad electrode 95 with the source regions 23 and 24 and the contact region 25. When the contact area is reduced, the contact resistance may increase.

Therefore, according to the semiconductor device 1, since the mesa contact portion 41 is formed in the contact portion 40, the source pad electrode 95 can be brought into contact with both the mesa upper portion 43 and the mesa side portion 44. As a result, the contact resistance to the source regions 23 and 24 and the contact region 25 can be reduced as compared with a case where the contact portion 40 is formed only by a flat surface. Therefore, it is possible to meet a demand for narrowing the pitch of the gate structure 30 and to reduce the contact resistance.

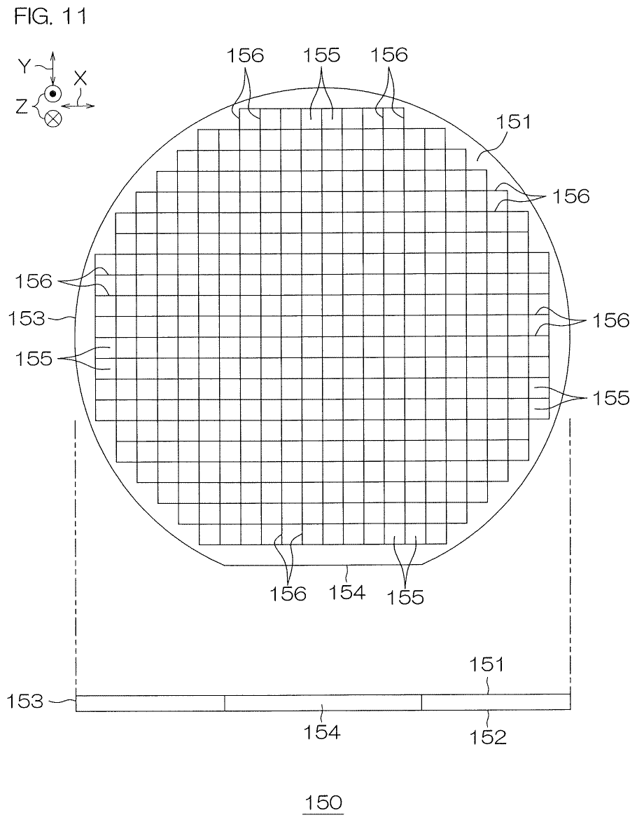

FIG. 11 is a schematic view illustrating a wafer 150 used for manufacturing the semiconductor device 1. Referring to FIG. 11, the wafer 150 is a base material of the chip 2 and includes an SiC monocrystal. The wafer 150 is formed in a flat disc shape. As a matter of course, the wafer 150 may be formed in a flat rectangular parallelepiped shape. The wafer 150 has a first wafer principal surface 151 on one side, a second wafer principal surface 152 on the other side, and a wafer side surface 153 connecting the first wafer principal surface 151 and the second wafer principal surface 152.

The first wafer principal surface 151 corresponds to the first principal surface 3 of the chip 2, and the second wafer principal surface 152 corresponds to the second principal surface 4 of the chip 2. The first wafer principal surface 151 and the second wafer principal surface 152 are formed by the c-plane of the SiC monocrystal. The first wafer principal surface 151 is formed by a silicon plane of the SiC monocrystal, and the second wafer principal surface 152 is formed by a carbon plane of the SiC monocrystal. The wafer 150 (the first wafer principal surface 151 and the second wafer principal surface 152) has the above-described off direction and off angle.

The wafer 150 has a mark 154 indicating a crystal orientation of the SiC monocrystal on the wafer side surface 153. The mark 154 may include either or both of an orientation flat and an orientation notch. The orientation flat is constituted of a notched portion that is notched rectilinearly in plan view. The orientation notch is constituted of a notched portion that is notched in a recessed shape (for example, a tapered shape) toward a central portion of the first wafer principal surface 151 in plan view.

The mark 154 may include either or both of a first orientation flat extending in the m-axis direction and a second orientation flat extending in the a-axis direction. The mark 154 may include either or both of an orientation notch recessed in the m-axis direction and an orientation notch recessed in the a-axis direction.

The wafer 150 includes the first semiconductor region 6 in a region (surface layer portion) on the first wafer principal surface 151 side. The first semiconductor region 6 is formed in a layer shape extending along the first wafer principal surface 151. In this embodiment, the first semiconductor region 6 consists of an epitaxial layer (specifically, an SiC epitaxial layer).

The wafer 150 includes the second semiconductor region 7 in a region (surface layer portion) on the second wafer principal surface 152 side. The second semiconductor region 7 is formed in a layer shape extending along the second principal surface 4 and is electrically connected to the first semiconductor region 6. In this embodiment, the second semiconductor region 7 is constituted of a wafer main body (specifically, an SiC wafer). That is, in this embodiment, the wafer 150 is constituted of an epitaxial wafer (so-called epi-wafer) having a laminated structure including the wafer main body and the epitaxial layer.

For example, a plurality of device regions 155 and a plurality of intended cutting lines 156 are set in the wafer 150 by an alignment mark, etc. Each device region 155 is a region corresponding to the semiconductor device 1. The plurality of device regions 155 are each set in a quadrangular shape in plan view.

In this embodiment, the plurality of device regions 155 are set in a matrix along the first direction X and the second direction Y in plan view. The plurality of device regions 155 are each set at an interval inward from the peripheral edge of the first wafer principal surface 151 in plan view. The plurality of intended cutting lines 156 are set in a lattice extending along the first direction X and the second direction Y such as to demarcate the plurality of device regions 155.

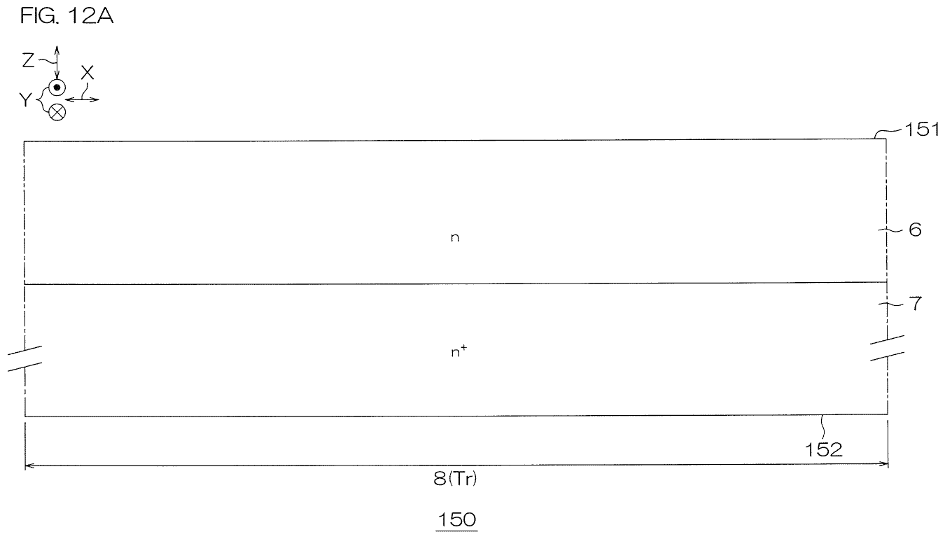

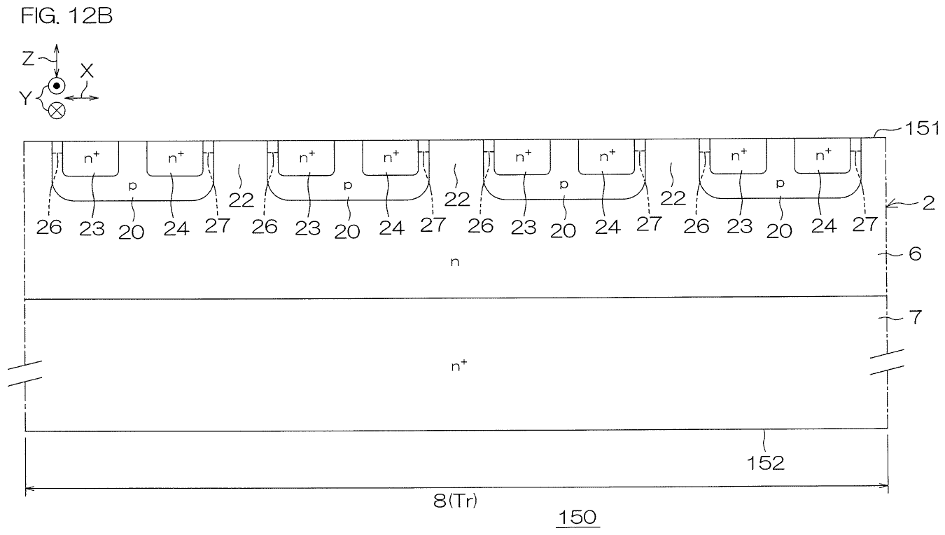

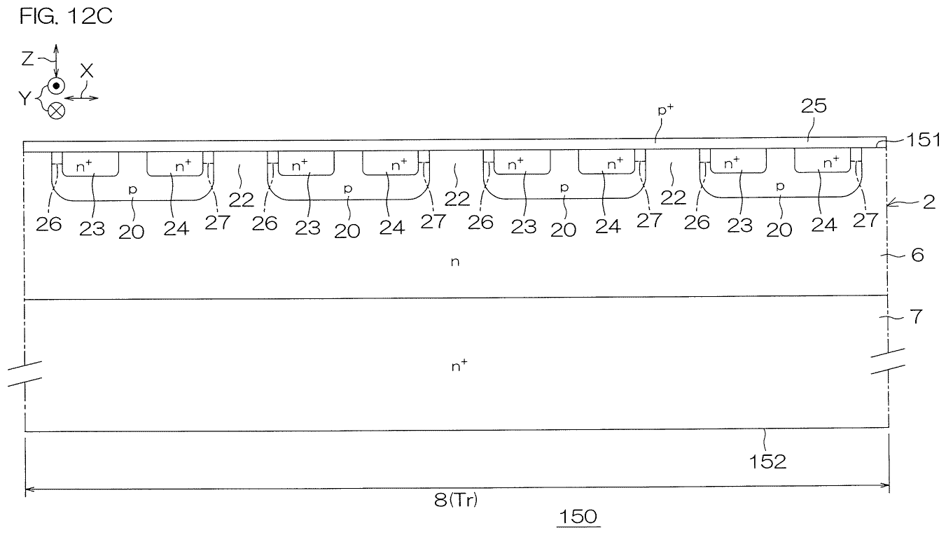

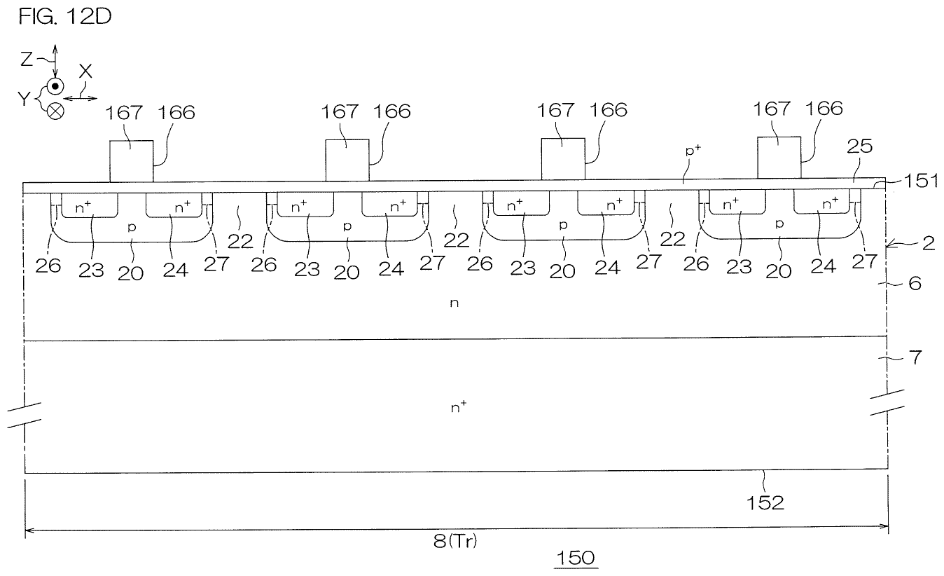

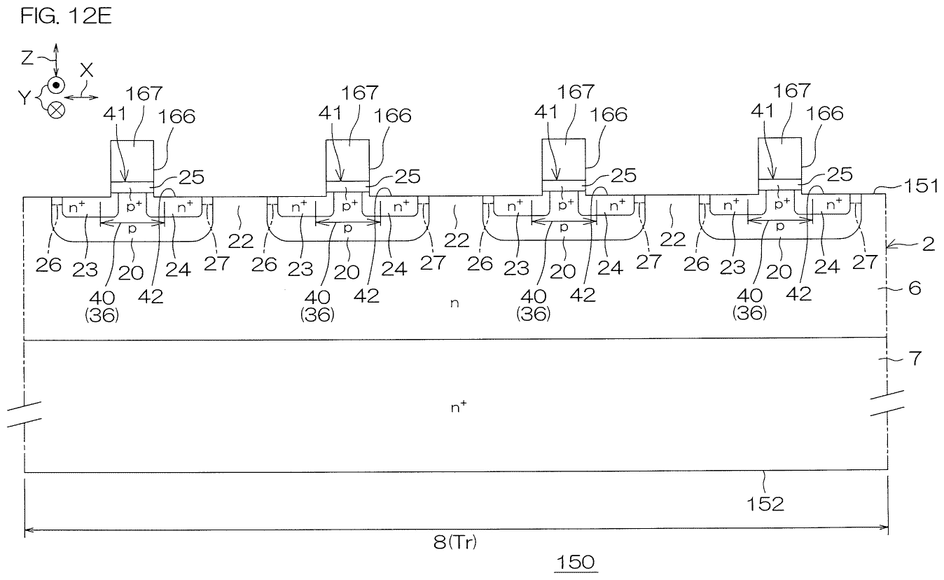

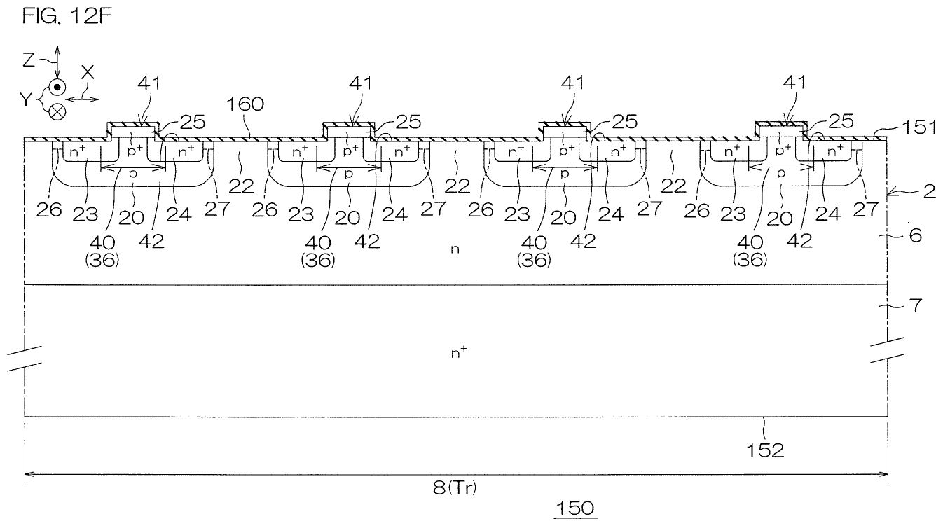

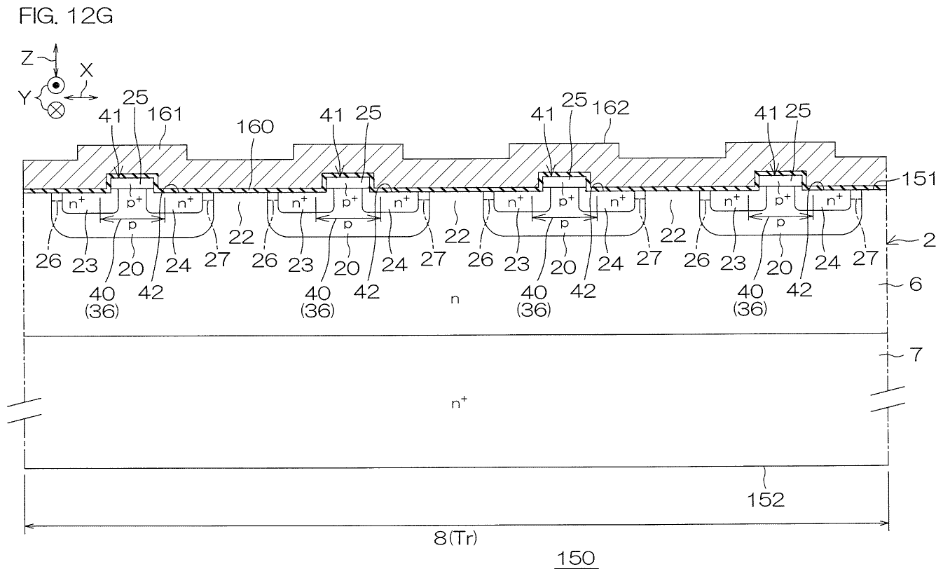

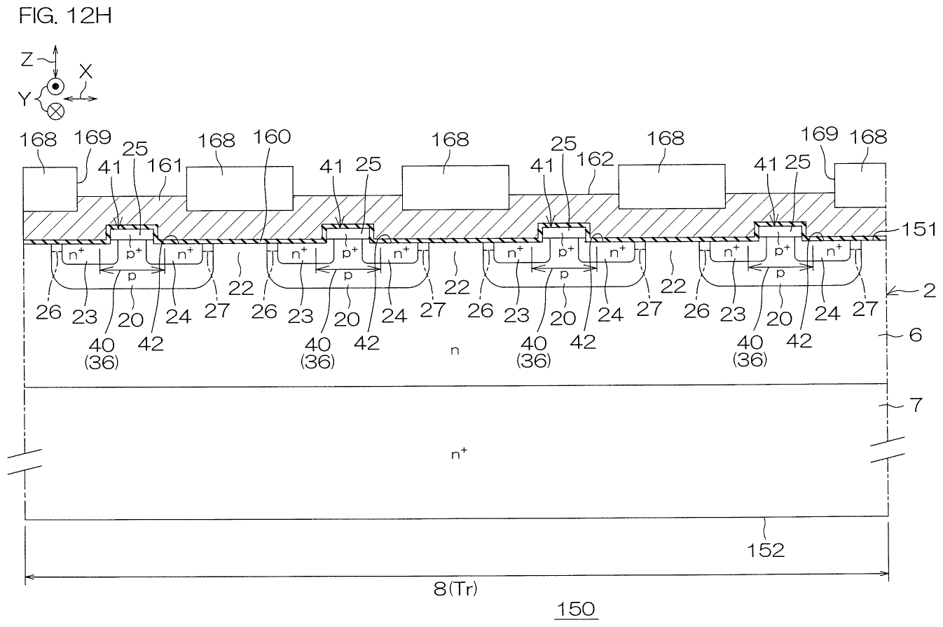

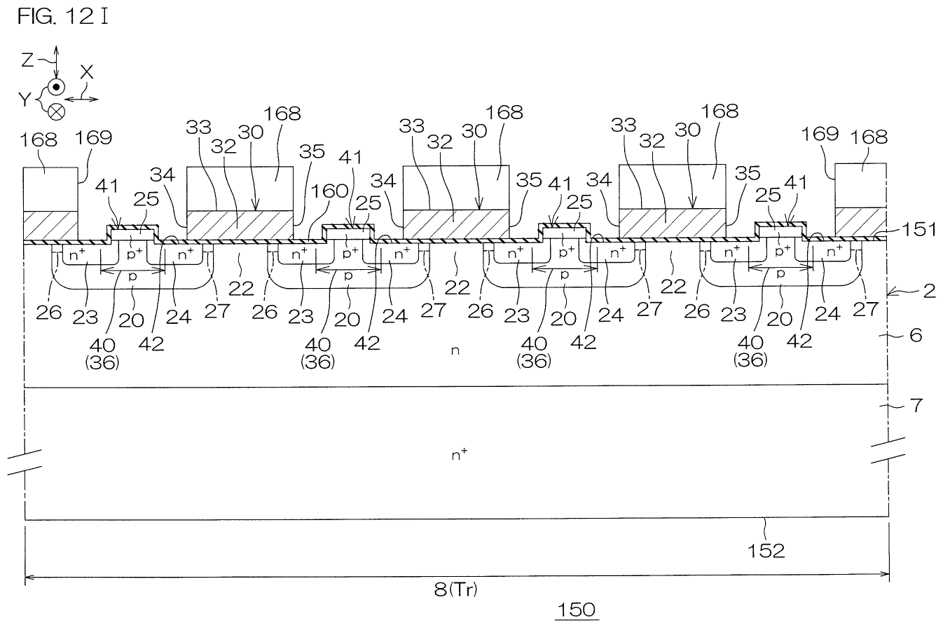

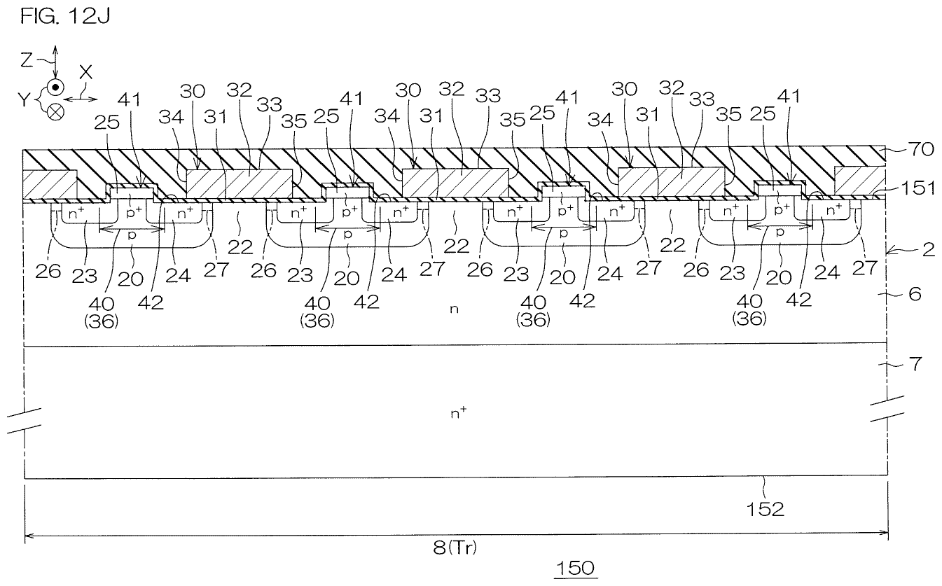

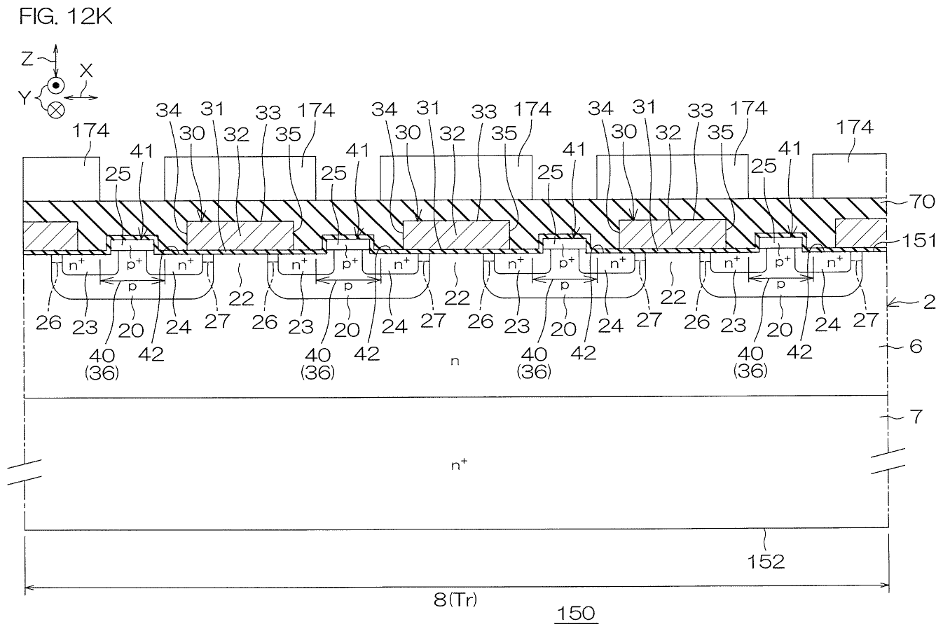

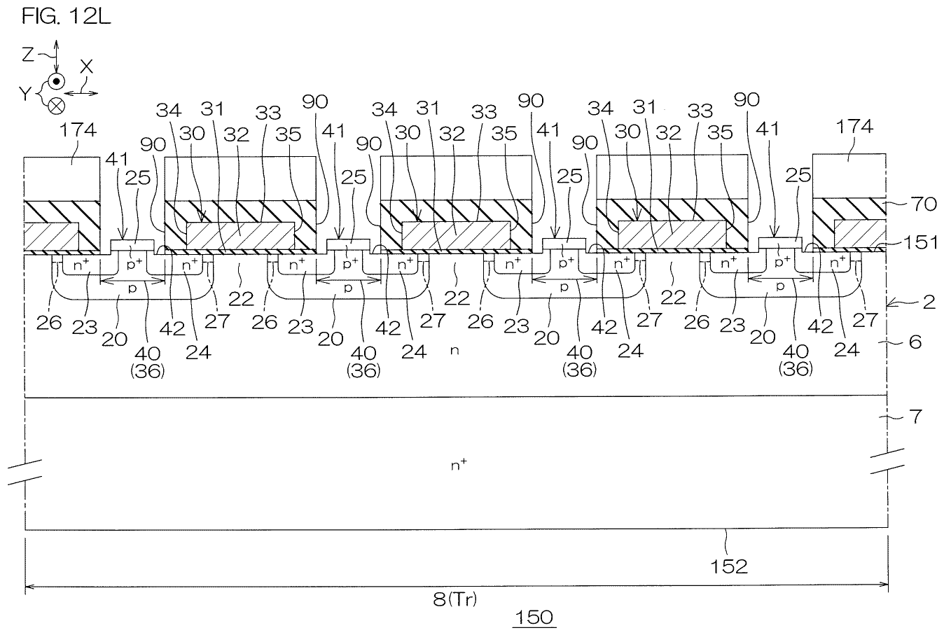

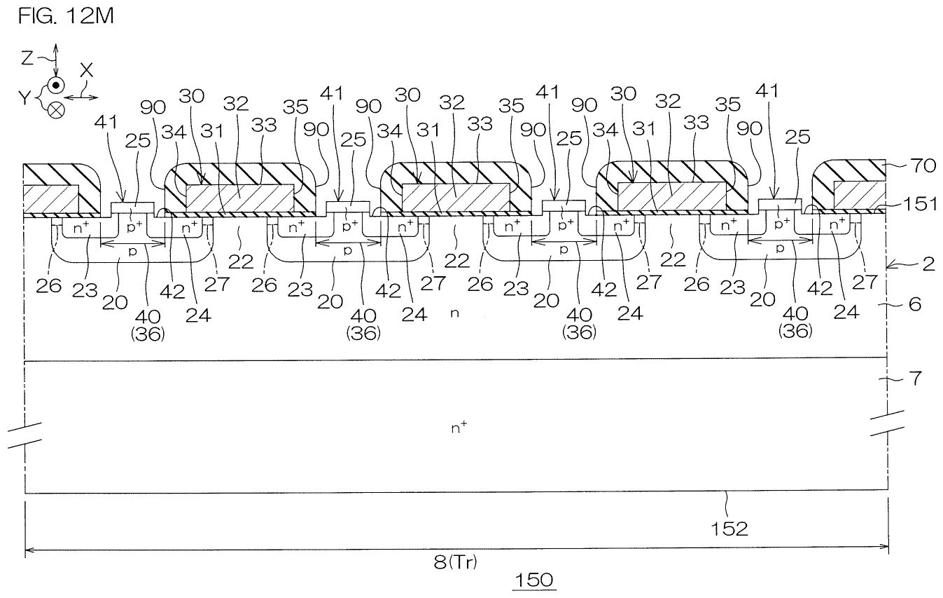

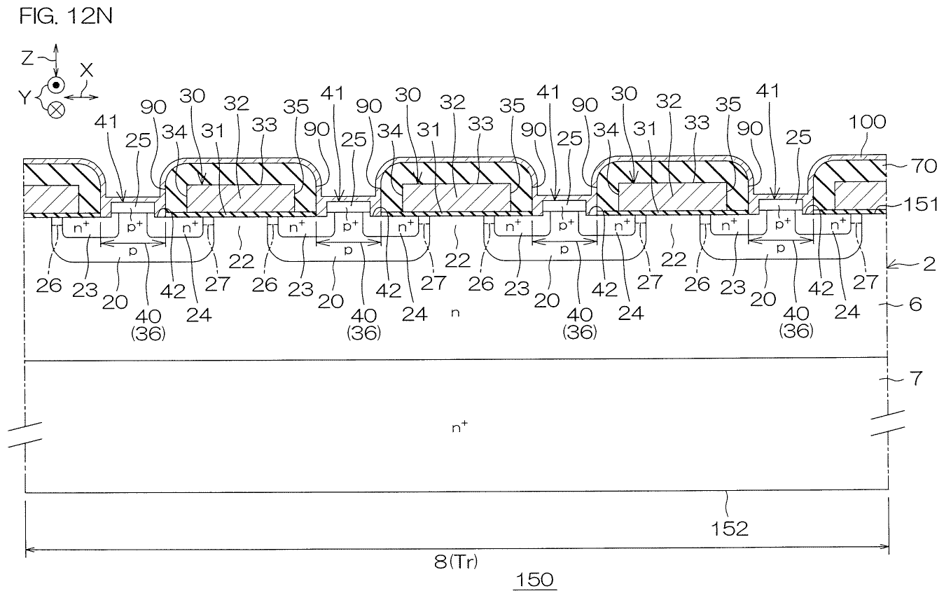

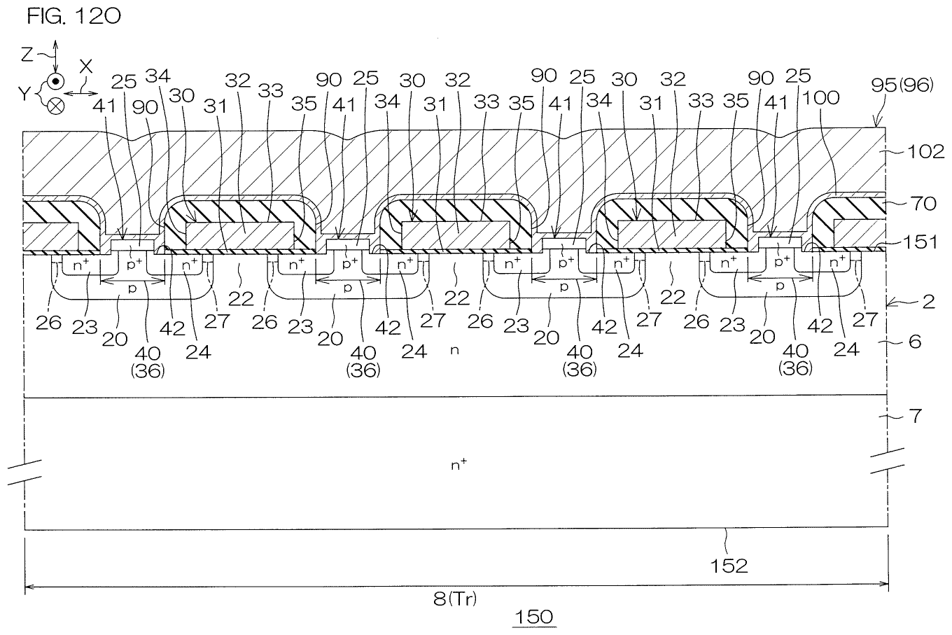

FIGS. 12A to 12O are cross-sectional views illustrating a method for manufacturing the semiconductor device 1. In FIGS. 12A to 12O, a cross-section of a portion of the active region 8 of one device region 155 is shown.

Referring to FIG. 12A, first, the above-described wafer 150 is prepared. Next, referring to FIG. 12B, a p-type impurity is selectively introduced into a surface layer portion of the first wafer principal surface 151 by an ion implantation method through a mask (not illustrated), and the plurality of body regions 20 are formed. In addition, a p-type impurity is selectively introduced into the surface layer portion of the first wafer principal surface 151 by the ion implantation method through a mask (not illustrated), and the outer body region 21 is formed. In addition, an n-type impurity is selectively introduced into the surface layer portion of the first wafer principal surface 151 by the ion implantation method through a mask (not illustrated), and the plurality of source regions 23 and 24 are formed.

Next, referring to FIG. 12C, a p-type impurity is selectively introduced into the entire surface layer portion of the first wafer principal surface 151, and the contact region 25 is formed.

Next, referring to FIG. 12D, a mask 167 having a predetermined layout is formed on the first wafer principal surface 151 (contact region 25). The mask 167 may be an organic mask (for example, a resist mask). The mask 167 covers regions where the plurality of mesa contact portions 41 are to be formed and has a plurality of openings 166 that expose other regions.

Next, referring to FIG. 12E, an unnecessary portion of the wafer 150 is removed in the thickness direction. In this step, the wafer 150 is removed by an etching method through the mask 167. The etching method may be a wet etching method and/or a dry etching method, but a dry etching method is preferable. As a result, the portion of the wafer 150 protected by the mask 167 remains as the mesa contact portion 41, and the other region is formed as the flat contact portion 42.

Next, referring to FIG. 12F, a base insulating film 160 covering the first wafer principal surface 151 is formed. The base insulating film 160 is a base of the insulating film 31 and the outer peripheral insulating film 51. The base insulating film 160 may be formed by a CVD (chemical vapor deposition) method or an oxidation treatment method (for example, a thermal oxidation treatment method).

Next, referring to FIG. 12G, a base electrode 161 is formed on the base insulating film 160. The base electrode 161 is a base of the gate electrode 32 and the gate wiring 52. The base electrode 161 contains a conductive polysilicon. The base electrode 161 may be formed by the CVD method. The base electrode 161 has a base electrode surface 162 extending along the base insulating film 160.

Next, referring to FIG. 12H, a mask 168 having a predetermined layout is formed on the base electrode 161 (base electrode surface 162). The mask 168 may be an organic mask (for example, a resist mask). The mask 168 has a plurality of openings 169 for exposing regions other than a plurality of mask portions covering regions where the plurality of gate electrodes 32 are to be formed.

Next, referring to FIG. 12I, an unnecessary portion of the base electrode 161 is removed in the thickness direction. In this step, the base electrode 161 is removed by the etching method through the mask 168. The etching method may be a wet etching method and/or a dry etching method. Thus, the plurality of gate electrodes 32 and the gate wiring 52 are formed. After the step of forming the gate electrode 32 and the gate wiring 52, the mask 168 is removed.

Next, referring to FIG. 12J, the interlayer film 70 is formed on the first wafer principal surface 151. In this step, the interlayer film 70 having a portion directly covering the gate electrode 32 is formed. In addition, the interlayer film 70 having a portion directly covering the gate wiring 52 is formed.

In this embodiment, the interlayer film 70 has a laminated structure including the first oxide film 72 and the second oxide film 73 (see FIG. 7). The first oxide film 72 includes a silicon oxide film that is not doped with an impurity. The second oxide film 73 includes a silicon oxide film containing phosphorus. The first oxide film 72 may be formed by the CVD method. The second oxide film 73 may be formed by the CVD method. After the step of forming the second oxide film 73, a reflow step (heat treatment step) is performed on the interlayer film 70.

As a result, corner portions and front surface roughness of the interlayer film 70 are smoothed.

Next, referring to FIG. 12K, a mask 174 having a predetermined layout is disposed on the interlayer film 70. The mask 174 exposes regions where the plurality of source openings 90, the plurality of outer openings 92, and the plurality of gate openings 94 are to be formed, and covers regions other than them.

Next, referring to FIG. 12L, an unnecessary portion of the interlayer film 70 and an unnecessary portion of the base insulating film 160 are removed by the etching method through the mask 174. In this step, an unnecessary portion of the second oxide film 73, an unnecessary portion of the first oxide film 72, and an unnecessary portion of the base insulating film 160 are removed in this order. The etching method may be a wet etching method and/or a dry etching method. The etching method is preferably an anisotropic dry etching method (for example, an RIE (reactive ion etching) method).

As a result, the plurality of source openings 90, the plurality of outer openings 92, and the plurality of gate openings 94 are formed in the interlayer film 70. In addition, the insulating film 31 and the outer peripheral insulating film 51 are formed. The mask 174 is then removed.

Next, referring to FIG. 12M, an upper corner portion of the interlayer film 70 is formed in an arcuate shape by a reflow process. A reflow condition is not particularly limited as long as the reflow condition is such that the upper corner portion of the interlayer film 70 that is pointed after etching in FIG. 12L becomes arcuate. For example, it may be appropriately determined according to the film thickness and film quality of the interlayer film 70, the opening width of the source opening 90, etc.

Next, referring to FIG. 12N, the first base electrode film 100 and the second base electrode film 120 are formed on the interlayer film 70. The first base electrode film 100 and the second base electrode film 120 may be formed by a sputtering method or a vapor deposition method.

Next, referring to FIG. 12O, the first principal electrode film 102 and the second principal electrode film 122 are formed on the first base electrode film 100 and the second base electrode film 120, respectively. The first principal electrode film 102 and the second principal electrode film 122 may include at least one among an Al film, an Al alloy film, a Cu film, and a Cu alloy film. The Al alloy film may include at least one among an AlSi alloy film, an AlCu alloy film, and an AlSiCu alloy film. The first principal electrode film 102 and the second principal electrode film 122 may be formed by the sputtering method or the vapor deposition method.

Thereafter, the drain pad electrode 140 is formed on the second wafer principal surface 152. The drain pad electrode 140 may be formed by the sputtering method or the vapor deposition method. Then, the wafer 150 is cut along the intended cutting line 156, and the plurality of semiconductor devices 1 are cut out. The semiconductor device 1 is manufactured through the steps including the above.

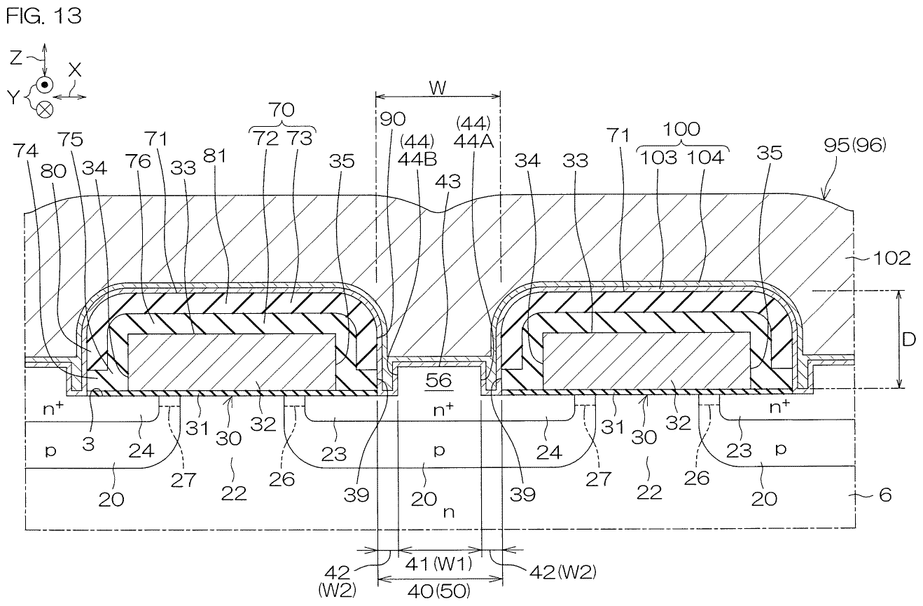

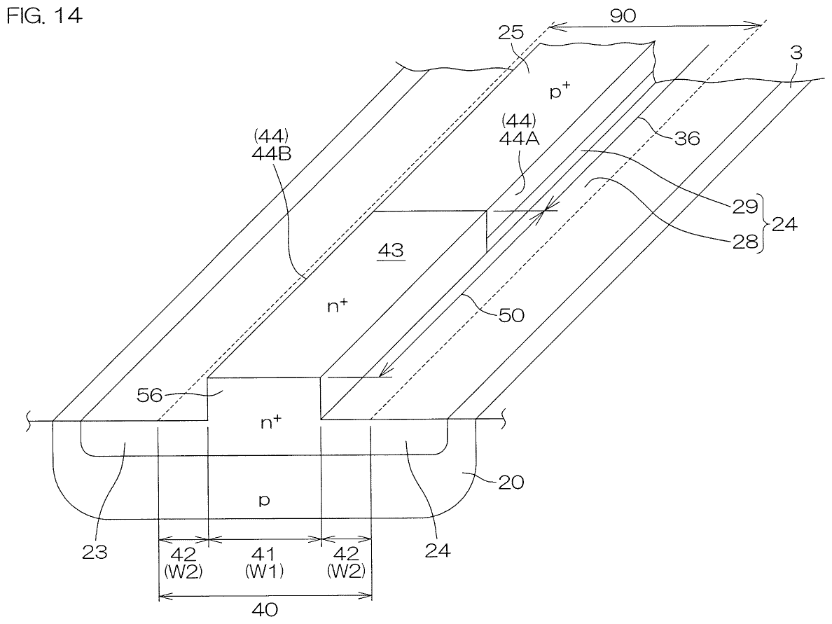

Hereinafter, a modification example of the mesa contact portion 41 will be described. FIG. 13 is a cross-sectional view illustrating a first modification example (second contact portion 50) of the mesa contact portion 41. FIG. 14 is a perspective view of the mesa contact portion 41 including the second contact portion 50 in FIG. 13.

In this embodiment, the mesa contact portion 41 includes an impurity region in the form of the second contact portion 50 in addition to the form of the first contact portion 36. Referring to FIG. 14, the first contact portion 36 and the second contact portion 50 are formed to be divided from each other along the stripe direction of the mesa contact portion 41 (the stripe direction of the gate structure 30). For example, in FIG. 14, the second contact portion 50 is formed in a band shape in the mesa contact portion 41, and the first contact portion 36 is formed continuously with the second contact portion 50.

In FIG. 14, the band-shaped second contact portion 50 and the band-shaped first contact portion 36 are formed one each, and the second contact portion 50 is positioned on the near side of the plane of paper, but the first contact portion 36 may be positioned on the near side of the plane of paper. In addition, the plurality of second contact portions 50 and the plurality of first contact portions 36 may be alternately arranged along the stripe direction of the mesa contact portion 41.

Referring to FIG. 14, in the second contact portion 50, the mesa contact portion 41 is formed by the source regions 23 and 24 across its entirety in the thickness direction from the mesa upper portion 43, and the source regions 23 and 24 are exposed from both the mesa upper portion 43 and the mesa side portion 44. The first source region 23 and the second source region 24 are integrally formed inside the mesa contact portion 41 as one source region 56 in the entire mesa contact portion 41 of the second contact portion 50.

In the second contact portion 50, the source region 56 is continuously formed on the mesa upper portion 43 and the mesa side portion 44 along the length direction of the mesa contact portion 41, and is exposed from three directions of the mesa upper portion 43 and the pair of mesa side portions 44A and 43B. Therefore, the source region 56 is exposed from an entire front surface of the mesa contact portion 41.

According to this configuration, the source pad electrode 95 can be brought into contact with the entire mesa upper portion 43 and mesa side portion 44 of the mesa contact portion 41 in the second contact portion 50. As a result, the contact area with respect to the source regions 23 and 24 can be reduced, and the contact resistance can be reduced.

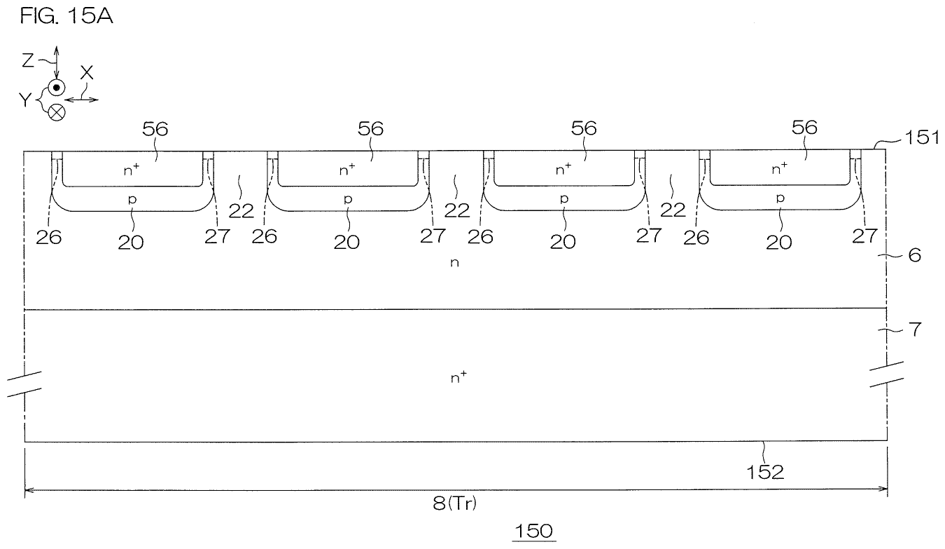

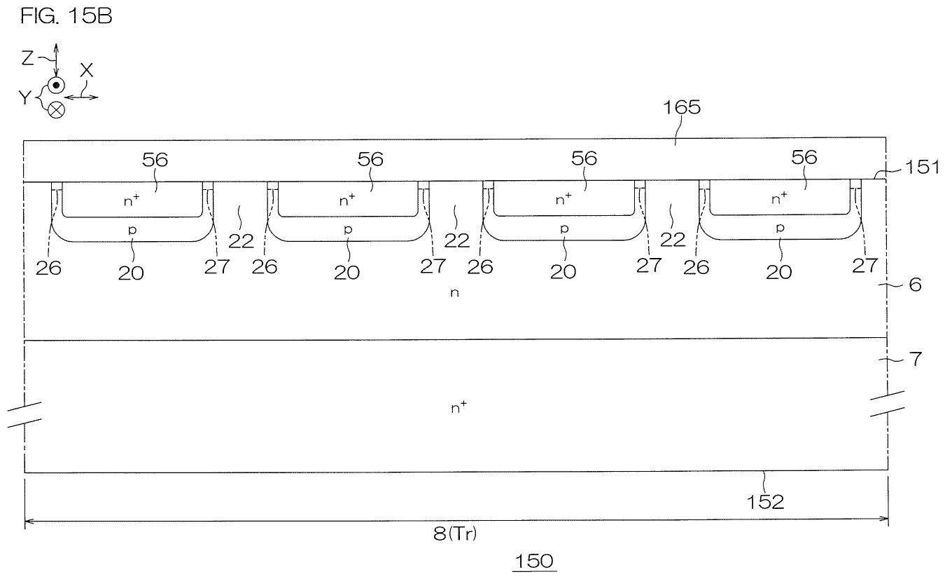

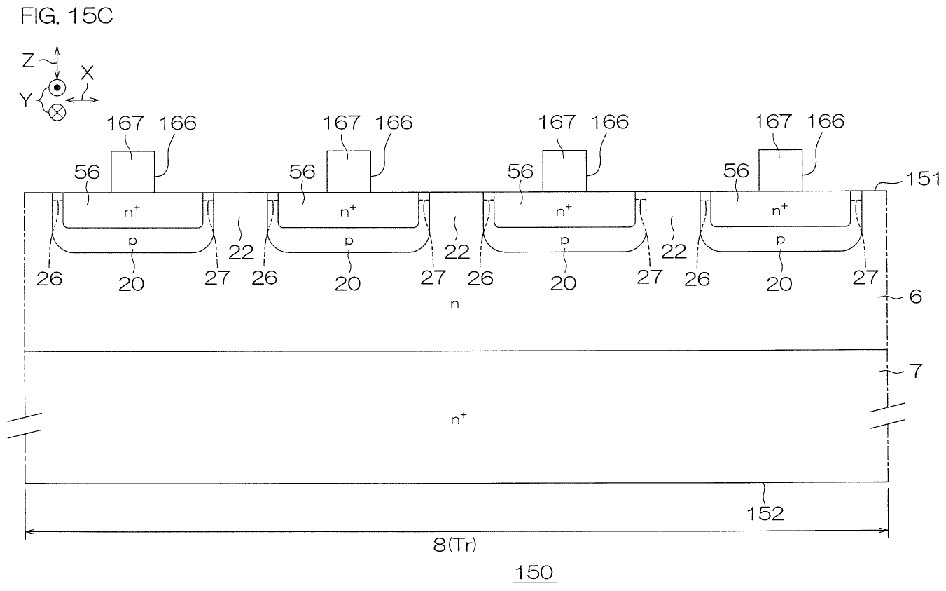

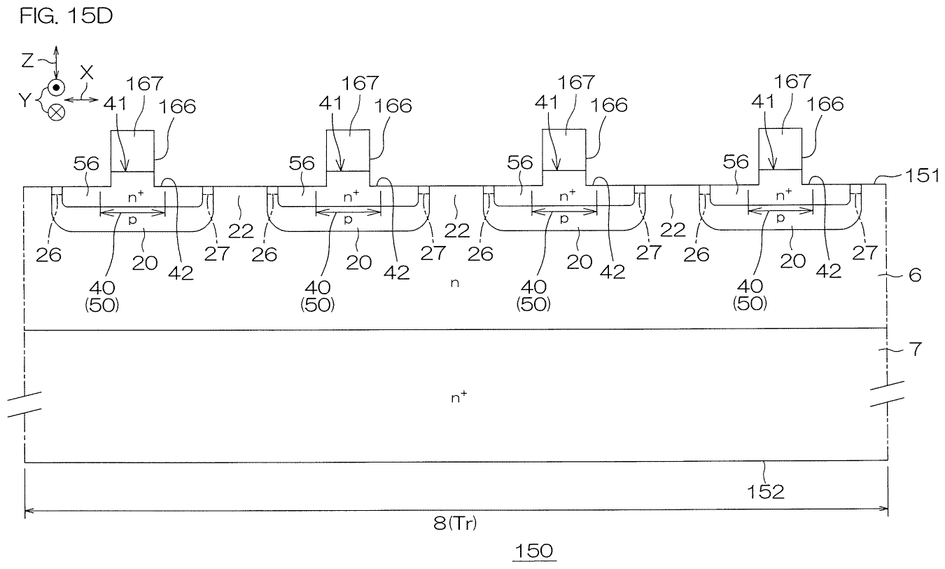

FIGS. 15A to 15D are views illustrating steps related to the formation of the second contact portion 50 in FIG. 13. The second contact portion 50 can be formed in parallel with the first contact portion 36 described above.

In order to form the second contact portion 50, for example, after the wafer 150 is prepared, referring to FIG. 15A, a p-type impurity is selectively introduced into the surface layer portion of the first wafer principal surface 151 by the ion implantation method through a mask (not illustrated), and the plurality of body regions 20 are formed. In addition, a p-type impurity is selectively introduced into the surface layer portion of the first wafer principal surface 151 by the ion implantation method through a mask (not illustrated), and the outer body region 21 is formed. In addition, an n-type impurity is selectively introduced into the surface layer portion of the first wafer principal surface 151 by the ion implantation method through a mask (not illustrated), and the plurality of source regions 56 are formed.

Next, referring to FIG. 15B, when the above-described contact region 25 is formed (see FIG. 12C), a region where the second contact portion 50 is to be formed is covered and protected by a mask 165. This prevents a p-type impurity from being introduced into the second contact portion 50.

Next, referring to FIG. 15C, the mask 167 having a predetermined layout is formed on the first wafer principal surface 151 (the contact region 25 and the source region 56). The mask 167 may be an organic mask (for example, a resist mask). The mask 167 covers regions where the plurality of mesa contact portions 41 are to be formed and has a plurality of openings 166 that expose other regions.

Next, referring to FIG. 15D, an unnecessary portion of the wafer 150 is removed in the thickness direction. In this step, the wafer 150 is removed by an etching method through the mask 167. The etching method may be a wet etching method and/or a dry etching method, but a dry etching method is preferable. As a result, the portion of the wafer 150 protected by the mask 167 remains as the mesa contact portion 41 (the first contact portion 36 and the second contact portion 50), and the other region is formed as the flat contact portion 42.

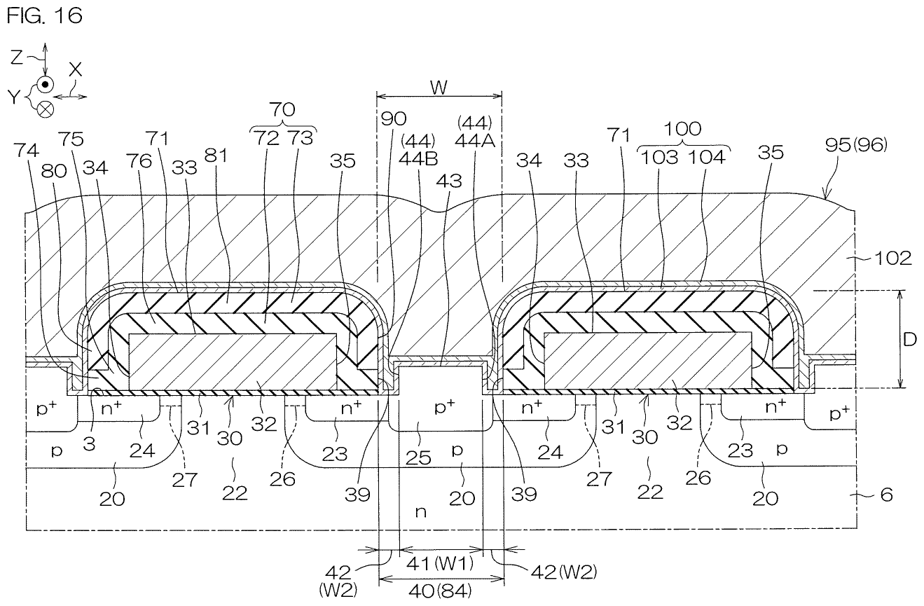

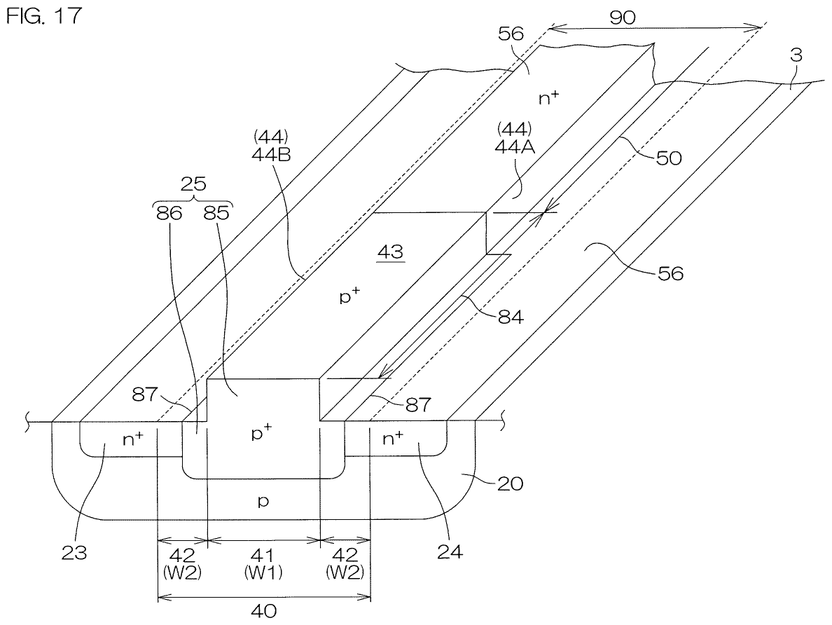

FIG. 16 is a cross-sectional view illustrating a second modification example (third contact portion 84) of the mesa contact portion 41. FIG. 17 is a perspective view of the mesa contact portion 41 including the third contact portion 84 in FIG. 16.

In this embodiment, the mesa contact portion 41 includes an impurity region in the form of the third contact portion 84 in addition to the form of the second contact portion 50. Referring to FIG. 17, the second contact portion 50 and the third contact portion 84 are formed to be divided from each other along the stripe direction of the mesa contact portion 41 (the stripe direction of the gate structure 30). For example, in FIG. 17, the third contact portion 84 is formed in a band shape in the mesa contact portion 41, and the second contact portion 50 is formed continuously with the third contact portion 84.

In FIG. 17, the band-shaped third contact portion 84 and the band-shaped second contact portion 50 are formed one each, and the third contact portion 84 is positioned on the near side of the plane of paper, but the second contact portion 50 may be positioned on the near side of the plane of paper. In addition, the plurality of third contact portions 84 and the plurality of second contact portions 50 may be alternately arranged along the stripe direction of the mesa contact portion 41.

Referring to FIG. 17, in the third contact portion 84, the mesa contact portion 41 is formed by the contact region 25 across its entirety in the thickness direction from the mesa upper portion 43, and the contact region 25 is exposed from both the mesa upper portion 43 and the mesa side portion 44. The contact region 25 penetrates through the first source region 23 and the second source region 24, and is connected to the body region 20 at a lower portion of the mesa contact portion 41.

The contact region 25 integrally includes a base portion 85 formed inside the mesa contact portion 41 and a lead-out portion 86 led out from the base portion 85 to the flat contact portion 42.

The base portion 85 is formed from the mesa upper portion 43 to a base portion of the mesa contact portion 41 in a depth direction, and is formed from the first mesa side portion 44A to the second mesa side portion 44B in a lateral direction. In this embodiment, the base portion 85 is formed to a position deeper than the source regions 23 and 24. As a result, the contact region 25 (base portion 85) is exposed from three directions of the mesa upper portion 43 and the pair of mesa side portions 44A and 43B. Therefore, the contact region 25 is exposed from the entire front surface of the mesa contact portion 41.

The lead-out portion 86 of the contact region 25 is led out from the base portion 85 to both sides in the lateral direction, and has a boundary surface 87 with the source regions 23 and 24 in the flat contact portion 42. The lead-out portion 86 is formed in a band shape along the stripe direction of the mesa contact portion 41. In this embodiment, the band-shaped lead-out portions 86 are formed on both sides in the lateral direction of the mesa contact portion 41, respectively, and the mesa contact portion 41 is sandwiched between the pair of lead-out portions 86. As a result, in each flat contact portion 42, the band-shaped contact region 25 (lead-out portion 86) and the source regions 23 and 24 are formed side by side along the stripe direction of the mesa contact portion 41.

According to this configuration, the source pad electrode 95 can be brought into contact with the entire mesa upper portion 43 and mesa side portion 44 of the mesa contact portion 41 in the third contact portion 84. As a result, the contact area with respect to the contact region 25 can be reduced, and the contact resistance can be reduced.

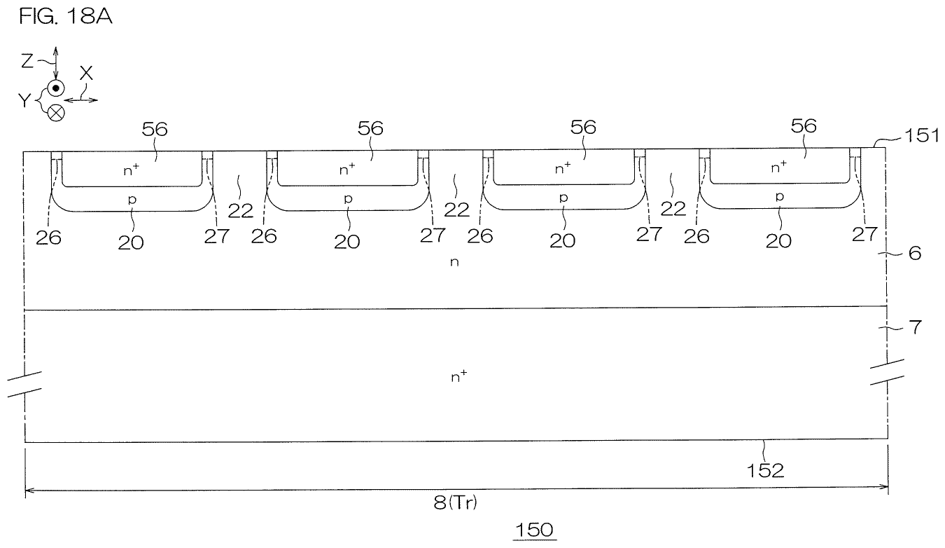

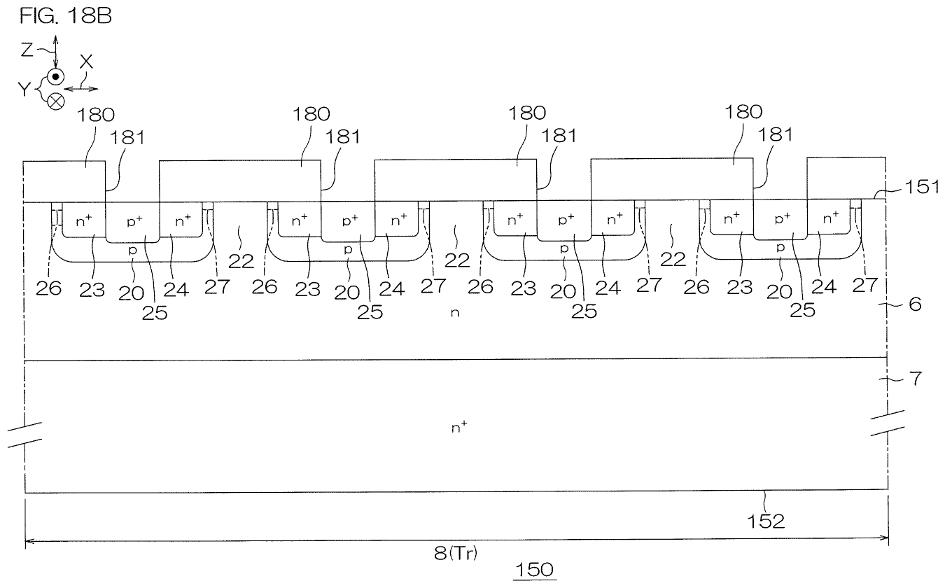

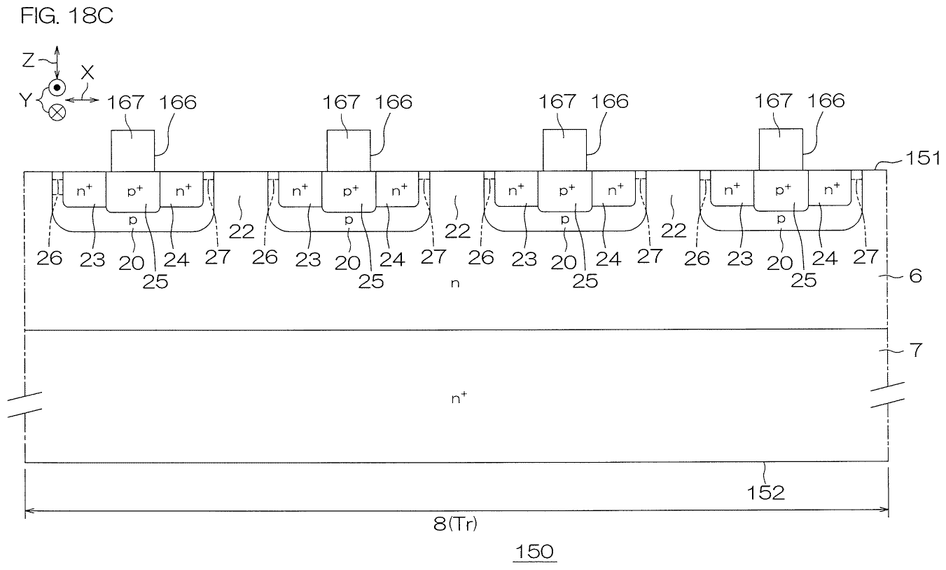

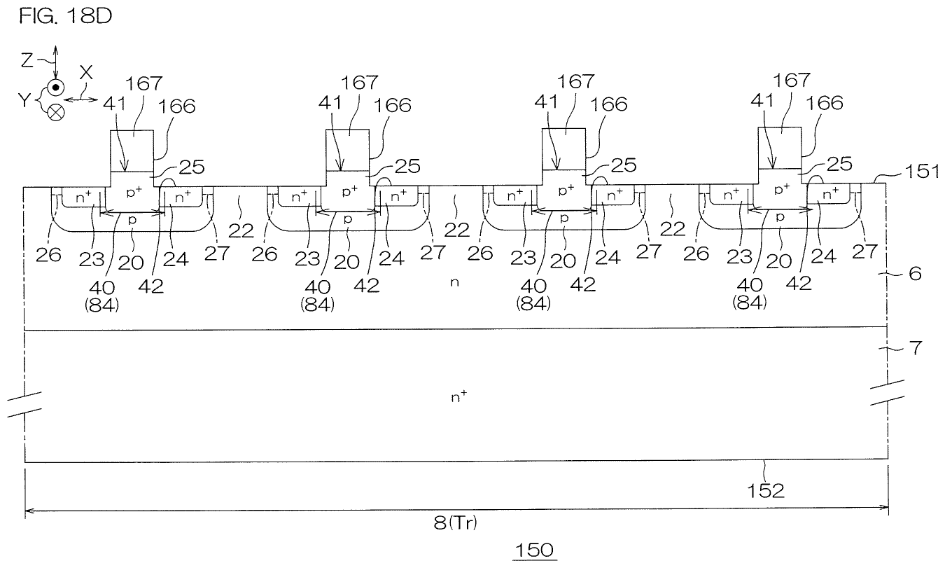

FIGS. 18A to 18D are views illustrating steps related to the formation of the third contact portion 84 in FIG. 16. The third contact portion 84 can be formed in parallel with the second contact portion 50 described above.

In order to form the third contact portion 84, for example, after the wafer 150 is prepared, referring to FIG. 18A, a p-type impurity is selectively introduced into the surface layer portion of the first wafer principal surface 151 by the ion implantation method through a mask (not illustrated), and the plurality of body regions 20 are formed. In addition, a p-type impurity is selectively introduced into the surface layer portion of the first wafer principal surface 151 by the ion implantation method through a mask (not illustrated), and the outer body region 21 is formed.

In addition, an n-type impurity is selectively introduced into the surface layer portion of the first wafer principal surface 151 by the ion implantation method through a mask (not illustrated), and the plurality of source regions 56 are formed.

Next, referring to FIG. 18B, a mask 180 having a predetermined layout is formed on the first wafer principal surface 151. The mask 180 may be an organic mask (for example, a resist mask). The mask 180 has openings 181 in regions where the plurality of contact regions 25 are to be formed, and covers other regions. For example, an entire region where the second contact portion 50 is to be formed is covered with the mask 180. Next, a p-type impurity is selectively introduced into the surface layer portion of the first wafer principal surface 151 by the ion implantation method through the mask 180, and the contact region 25 is formed.

Next, referring to FIG. 18C, the mask 167 having a predetermined layout is formed on the first wafer principal surface 151 (the contact region 25 and the source region 56). The mask 167 may be an organic mask (for example, a resist mask). The mask 167 covers regions where the plurality of mesa contact portions 41 are to be formed and has a plurality of openings 166 that expose other regions.

Next, referring to FIG. 18D, an unnecessary portion of the wafer 150 is removed in the thickness direction. In this step, the wafer 150 is removed by an etching method through the mask 167. The etching method may be a wet etching method and/or a dry etching method, but a dry etching method is preferable. As a result, the portion of the wafer 150 protected by the mask 167 remains as the mesa contact portion 41 (the second contact portion 50 and the third contact portion 84), and the other region is formed as the flat contact portion 42.

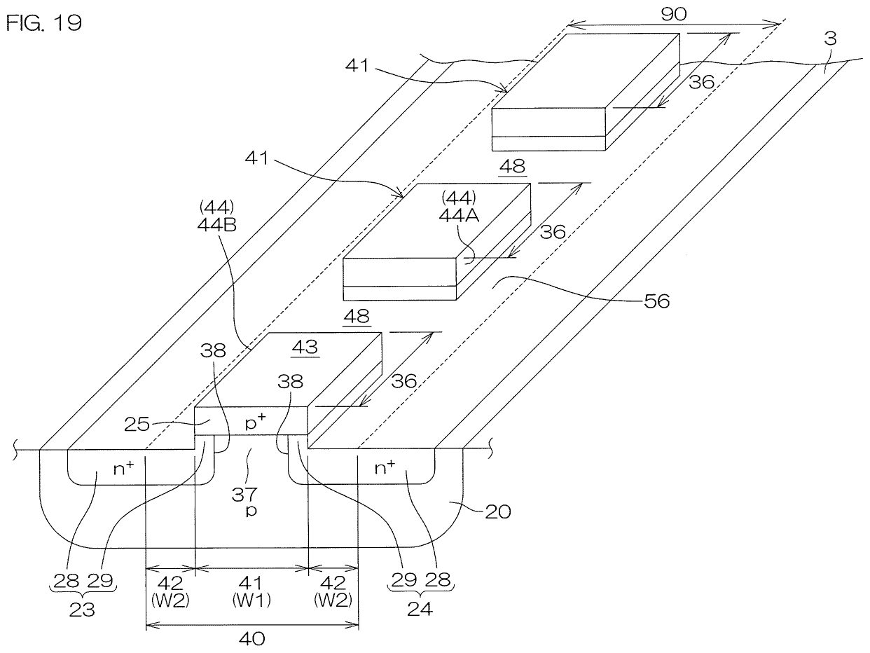

FIGS. 19 to 21 are cross-sectional views illustrating fourth to sixth modification examples of the mesa contact portion 41. Referring to FIGS. 19 to 21, in the contact portion 40, the plurality of mesa contact portions 41 may be arranged as dots at intervals along the stripe direction of the gate structure 30. A second flat contact portion 48 may be formed between the plurality of adjacent mesa contact portions 41.

In this embodiment, the second flat contact portion 48 extends between the pair of band-shaped flat contact portions 42 sandwiching the mesa contact portion 41. The source region 56 in which the source regions 23 and 24 are integrated is exposed from the second flat contact portion 48. As a result, in FIGS. 19 to 21, the source region 56 of ladder shape in plan view is exposed.

The mesa contact portions 41 arranged as dots may be unified as any one among the first contact portion 36, the second contact portion 50, and the third contact portion 84 described above, or may be combined with each other.

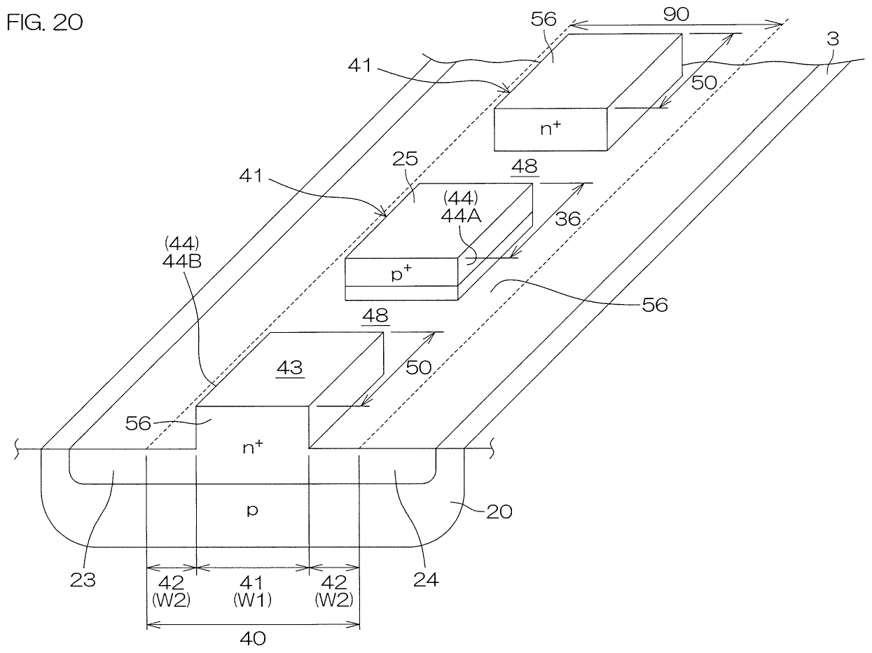

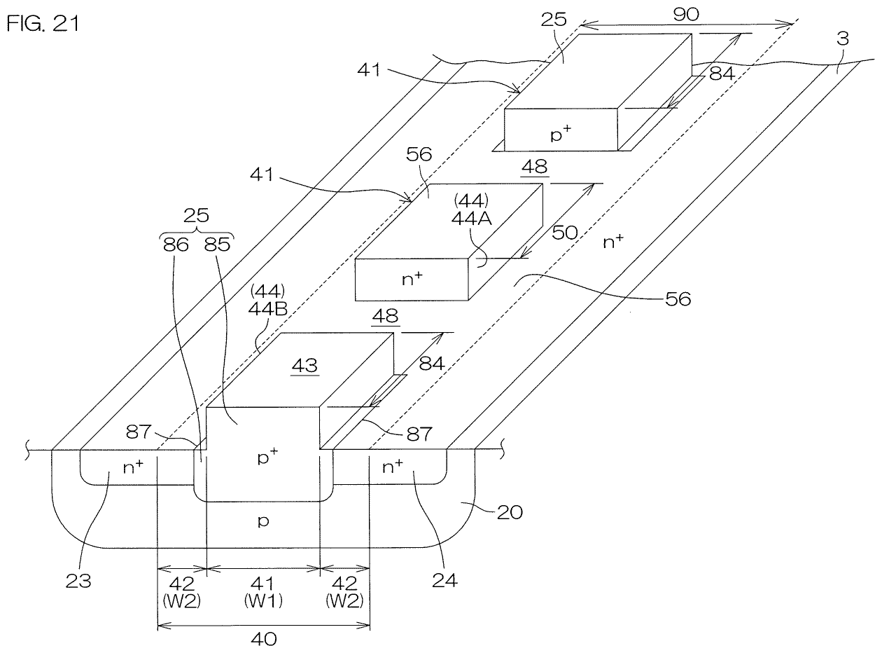

For example, in FIG. 19, all the mesa contact portions 41 are formed by the first contact portion 36. For example, FIG. 20 illustrates a combination of the mesa contact portion 41 formed by the second contact portion 50 and the mesa contact portion 41 formed by the first contact portion 36. For example, FIG. 21 illustrates a combination of the mesa contact portion 41 formed by the third contact portion 84 and the mesa contact portion 41 formed by the second contact portion 50.

Although the preferred embodiments of the present disclosure have been described above, the semiconductor device 1 of the present disclosure can be implemented in other embodiments.

The above-described preferred embodiments (including modification examples) can be implemented in yet other embodiments. For example, in each of the above-described preferred embodiments, a configuration in which a relationship between the a-axis direction and the m-axis direction is interchanged may be adopted. A specific configuration in this case can be obtained by interchanging the “a-axis direction (off direction)” and the “m-axis direction (direction orthogonal to off direction)” in the above description and the accompanying drawings.

In each of the above-described preferred embodiments, a structure in which the conductivity type of the “n-type” semiconductor region is inverted to the “p-type” and the conductivity type of the “p-type” semiconductor region is inverted to the “n-type” may be adopted.

A specific configuration in this case can be obtained by replacing the “n-type” with the “p-type” at the same time as replacing the “p-type” with the “n-type” in the above descriptions and the accompanying drawings.

In each of the above-described preferred embodiments, the chip 2 (the first semiconductor region 6 and the second semiconductor region 7) containing an SiC monocrystal is adopted.

However, the chip 2 (the first semiconductor region 6 and the second semiconductor region 7) may include a monocrystal of a wide bandgap semiconductor other than the SiC monocrystal. The wide bandgap semiconductor is a semiconductor having a bandgap greater than a bandgap of silicon. Examples of the monocrystal of the wide bandgap semiconductor include gallium nitride, diamond, gallium oxide, etc. As a matter of course, the chip 2 (the first semiconductor region 6 and the second semiconductor region 7) may contain a silicon monocrystal.

In each of the above-described preferred embodiments, the second semiconductor region 7 of the n-type has been illustrated. However, the p-type second semiconductor region 7 may be adopted instead of the n-type second semiconductor region 7. In this case, an IGBT (insulated gate bipolar transistor) structure is formed in place of the MISFET structure. In this case, in the above descriptions, the “source” of the MISFET structure is replaced with an “emitter” of the IGBT structure and the “drain” of the MISFET structure is replaced with a “collector” of the IGBT structure. The second semiconductor region 7 of the p-type may be an impurity region that contains a p-type impurity introduced into a surface layer portion of the second principal surface 4 of the chip 2 by the ion implantation method.

Hereinafter, examples of features extracted from this description and the attached drawings shall be indicated. Hereinafter, the alphanumeric characters, etc., in parentheses represent the corresponding components, etc., in the preferred embodiments described above, but are not intended to limit the scope of each clause to the preferred embodiments. The “semiconductor device” in the following clauses may be replaced with an “SiC semiconductor device,” a “wide bandgap semiconductor device,” a “semiconductor switching device,” a “MISFET device,” an “IGBT device,” etc., as needed.

### Appendix 1-1

A semiconductor device (1), including:
a chip (2) having a principal surface (3);
a gate electrode (32) formed on the principal surface (3);
an interlayer film (70) covering the gate electrode (32);
an opening (90) formed in the interlayer film (70) such as to be separated from the gate electrode (32) in a lateral direction along the principal surface (3) and exposing a part of the chip (2) as a contact portion (40); and
a front surface electrode (95) formed on the interlayer film (70) and mechanically and electrically connected to the contact portion (40) in the opening (90),
wherein the contact portion (40) includes a mesa contact portion (41) that protrudes from the principal surface (3) and has a mesa side portion (44) and a mesa upper portion (43), and
the front surface electrode (95) covers the mesa side portion (44) and the mesa upper portion (43).

According to this configuration, the front surface electrode (95) can be brought into contact with both the mesa side portion (44) and the mesa upper portion (43). As a result, contact resistance to the contact portion (40) can be reduced as compared with a case where the contact portion (40) is formed only by a flat surface.

### Appendix 1-2

The semiconductor device (1) according to Appendix 1-1, further including:
the plurality of gate electrodes (32) arranged at intervals on the principal surface (3),
wherein the opening (90) is demarcated in a region between the plurality of gate electrodes (32), and
the contact portion (40) includes the mesa contact portion (41) formed such as to be separated inward from both side walls of the opening (90), and a flat contact portion (42) formed by a part of the principal surface (3) between the mesa contact portion (41) and the side wall of the opening (90).

### Appendix 1-3

The semiconductor device (1) according to Appendix 1-2, wherein
the plurality of gate electrodes (32) are formed in a stripe shape,
the mesa contact portion (41) is formed in a stripe shape along a stripe direction of the gate electrode (32), and
a pair of the flat contact portions (42) sandwiching the mesa contact portion (41) are formed in a stripe shape side by side with the mesa contact portion (41).

### Appendix 1-4

The semiconductor device (1) according to Appendix 1-2 or Appendix 1-3, further including:
a semiconductor region (6) of a first conductivity type formed in a surface layer portion of the principal surface (3);
a body region (20) of a second conductivity type formed in a surface layer portion of the semiconductor region (6);
an impurity region (23, 24) of the first conductivity type formed in a surface layer portion of the body region (20);
a channel (26, 27) formed in a region between the semiconductor region (6) and the impurity region (23, 24) in the surface layer portion of the body region (20); and
an insulating film (31) covering the channel (26, 27) on the principal surface (3) and sandwiched between the gate electrode (32) and the channel (26, 27),
wherein the impurity region (23, 24) is exposed at least from the mesa side portion (44) and the flat contact portion (42) and is connected to the front surface electrode (95).

### Appendix 1-5

The semiconductor device (1) according to Appendix 1-4, wherein the mesa contact portion (41) includes a first contact portion (40) including a body protrusion portion (37) formed by a part of the body region (20) and passing through a side of the impurity region (23, 24) toward the mesa upper portion (43), a body contact region (25) of the second conductivity type connected to the body protrusion portion (37) at the mesa upper portion (43), and the impurity region (23, 24) formed around the body protrusion portion (37) and exposed from the mesa side portion (44).

### Appendix 1-6

The semiconductor device (1) according to Appendix 1-5, wherein the mesa contact portion (41) further includes a second contact portion (50) that is formed by the impurity region (23, 24) across its entirety in a thickness direction from the mesa upper portion (43), and in which the impurity region (23, 24) is exposed from both the mesa upper portion (43) and the mesa side portion (44).

### Appendix 1-7

The semiconductor device (1) according to Appendix 1-6, wherein the first contact portion (40) and the second contact portion (50) are formed to be divided from each other along the stripe direction of the gate electrode (32).

### Appendix 1-8

The semiconductor device (1) according to Appendix 1-4, wherein the mesa contact portion (41) includes
a second contact portion (50) that is formed by the impurity region (23, 24) across its entirety in a thickness direction from the mesa upper portion (43), and in which the impurity region (23, 24) is exposed from both the mesa upper portion (43) and the mesa side portion (44), and
a third contact portion (84) that is formed across its entirety in the thickness direction from the mesa upper portion (43), is connected to the body region (20) at a lower portion of the mesa contact portion (41), and is formed by a body contact region (25) of the second conductivity type exposed from both the mesa upper portion (43) and the mesa side portion (44).

### Appendix 1-9

The semiconductor device (1) according to Appendix 1-8, wherein the second contact portion (50) and the third contact portion (84) are formed to be divided from each other along the stripe direction of the mesa contact portion (41).

### Appendix 1-10

The semiconductor device (1) according to Appendix 1-2, wherein
the plurality of gate electrodes (32) are formed in a stripe shape,
the plurality of mesa contact portions (41) are arranged at intervals along the stripe direction of the gate electrode (32),
a pair of the flat contact portions (42) sandwiching the mesa contact portion (41) are formed in a stripe shape side by side with the mesa contact portion (41), and
the contact portion (40) further includes a second flat contact portion (48) formed between the plurality of adjacent mesa contact portions (41).

### Appendix 1-11

The semiconductor device (1) according to Appendix 1-10, further including:
a semiconductor region (6) of a first conductivity type formed in a surface layer portion of the principal surface (3);
a body region (20) of a second conductivity type formed in a surface layer portion of the semiconductor region (6);
an impurity region (23, 24) of the first conductivity type formed in a surface layer portion of the body region (20);
a channel (26, 27) formed in a region between the semiconductor region (6) and the impurity region (23, 24) in the surface layer portion of the body region (20); and
an insulating film (31) covering the channel (26, 27) on the principal surface (3) and sandwiched between the gate electrode (32) and the channel (26, 27),
wherein the impurity region (23, 24) is exposed at least from the mesa side portion (44), the flat contact portion (42) and the second flat contact portion (48), and is connected to the front surface electrode (95).

### Appendix 1-12

The semiconductor device (1) according to Appendix 1-11, wherein the mesa contact portion (41) includes a first contact portion (40) including a body protrusion portion (37) formed by a part of the body region (20) and passing through a side of the impurity region (23, 24) toward the mesa upper portion (43), a body contact region (25) of the second conductivity type connected to the body protrusion portion (37) at the mesa upper portion (43), and the impurity region (23, 24) formed around the body protrusion portion (37) and exposed from the mesa side portion (44).

### Appendix 1-13

The semiconductor device (1) according to Appendix 1-12, wherein the mesa contact portion (41) further includes a second contact portion (50) that is formed by the impurity region (23, 24) across its entirety in a thickness direction from the mesa upper portion (43), and in which the impurity region (23, 24) is exposed from both the mesa upper portion (43) and the mesa side portion (44).

### Appendix 1-14

The semiconductor device (1) according to Appendix 1-13, wherein the first contact portion (40) and the second contact portion (50) are formed apart from each other along the stripe direction of the gate electrode (32).

### Appendix 1-15

The semiconductor device (1) according to Appendix 1-11, wherein the mesa contact portion (41) includes
a second contact portion (50) that is formed by the impurity region (23, 24) across its entirety in a thickness direction from the mesa upper portion (43), and in which the impurity region (23, 24) is exposed from both the mesa upper portion (43) and the mesa side portion (44), and
a third contact portion (84) that is formed across its entirety in the thickness direction from the mesa upper portion (43), is connected to the body region (20) at a lower portion of the mesa contact portion (41), and is formed by a body contact region (25) of the second conductivity type exposed from both the mesa upper portion (43) and the mesa side portion (44).

### Appendix 1-16

The semiconductor device (1) according to Appendix 1-15, wherein the second contact portion (50) and the third contact portion (84) are formed apart from each other along the stripe direction of the gate electrode (32).

### Appendix 1-17

The semiconductor device (1) according to any one of Appendix 1-1 to Appendix 1-16, wherein the chip (2) is an SiC chip (2).

1. A semiconductor device comprising:
a chip having a principal surface;
a gate electrode formed on the principal surface;
an interlayer film covering the gate electrode;
an opening formed in the interlayer film such as to be separated from the gate electrode in a lateral direction along the principal surface and exposing a part of the chip as a contact portion; and
a front surface electrode formed on the interlayer film and mechanically and electrically connected to the contact portion in the opening,
wherein the contact portion includes a mesa contact portion that protrudes from the principal surface and has a mesa side portion and a mesa upper portion, and
the front surface electrode covers the mesa side portion and the mesa upper portion.

2. The semiconductor device according to claim 1, further comprising:
the plurality of gate electrodes arranged at intervals on the principal surface,
wherein the opening is demarcated in a region between the plurality of gate electrodes, and
the contact portion includes the mesa contact portion formed such as to be separated inward from both side walls of the opening, and a flat contact portion formed by a part of the principal surface between the mesa contact portion and the side wall of the opening.

3. The semiconductor device according to claim 2, wherein
the plurality of gate electrodes are formed in a stripe shape,
the mesa contact portion is formed in a stripe shape along a stripe direction of the gate electrode, and
a pair of the flat contact portions sandwiching the mesa contact portion are formed in a stripe shape side by side with the mesa contact portion.

4. The semiconductor device according to claim 2, further comprising:
a semiconductor region of a first conductivity type formed in a surface layer portion of the principal surface;
a body region of a second conductivity type formed in a surface layer portion of the semiconductor region;
an impurity region of the first conductivity type formed in a surface layer portion of the body region;
a channel formed in a region between the semiconductor region and the impurity region in the surface layer portion of the body region; and
an insulating film covering the channel on the principal surface and sandwiched between the gate electrode and the channel,
wherein the impurity region is exposed at least from the mesa side portion and the flat contact portion and is connected to the front surface electrode.

5. The semiconductor device according to claim 4, wherein the mesa contact portion includes a first contact portion including a body protrusion portion formed by a part of the body region and passing through a side of the impurity region toward the mesa upper portion, a body contact region of the second conductivity type connected to the body protrusion portion at the mesa upper portion, and the impurity region formed around the body protrusion portion and exposed from the mesa side portion.

6. The semiconductor device according to claim 5, wherein the mesa contact portion further includes a second contact portion that is formed by the impurity region across its entirety in a thickness direction from the mesa upper portion, and in which the impurity region is exposed from both the mesa upper portion and the mesa side portion.

7. The semiconductor device according to claim 6, wherein the first contact portion and the second contact portion are formed to be divided from each other along the stripe direction of the gate electrode.

8. The semiconductor device according to claim 4, wherein the mesa contact portion includes
a second contact portion that is formed by the impurity region across its entirety in a thickness direction from the mesa upper portion, and in which the impurity region is exposed from both the mesa upper portion and the mesa side portion, and
a third contact portion that is formed across its entirety in the thickness direction from the mesa upper portion, is connected to the body region at a lower portion of the mesa contact portion, and is formed by a body contact region of the second conductivity type exposed from both the mesa upper portion and the mesa side portion.

9. The semiconductor device according to claim 8, wherein the second contact portion and the third contact portion are formed to be divided from each other along the stripe direction of the mesa contact portion.

10. The semiconductor device according to claim 2, wherein
the plurality of gate electrodes are formed in a stripe shape,
the plurality of mesa contact portions are arranged at intervals along the stripe direction of the gate electrode,
a pair of the flat contact portions sandwiching the mesa contact portion are formed in a stripe shape side by side with the mesa contact portion, and
the contact portion further includes a second flat contact portion formed between the plurality of adjacent mesa contact portions.

11. The semiconductor device according to claim 10, further comprising:
a semiconductor region of a first conductivity type formed in a surface layer portion of the principal surface;
a body region of a second conductivity type formed in a surface layer portion of the semiconductor region;
an impurity region of the first conductivity type formed in a surface layer portion of the body region;
a channel formed in a region between the semiconductor region and the impurity region in the surface layer portion of the body region; and
an insulating film covering the channel on the principal surface and sandwiched between the gate electrode and the channel,
wherein the impurity region is exposed at least from the mesa side portion, the flat contact portion and the second flat contact portion, and is connected to the front surface electrode.

12. The semiconductor device according to claim 11, wherein the mesa contact portion includes a first contact portion including a body protrusion portion formed by a part of the body region and passing through a side of the impurity region toward the mesa upper portion, a body contact region of the second conductivity type connected to the body protrusion portion at the mesa upper portion, and the impurity region formed around the body protrusion portion and exposed from the mesa side portion.

13. The semiconductor device according to claim 12, wherein the mesa contact portion further includes a second contact portion that is formed by the impurity region across its entirety in a thickness direction from the mesa upper portion, and in which the impurity region is exposed from both the mesa upper portion and the mesa side portion.

14. The semiconductor device according to claim 13, wherein the first contact portion and the second contact portion are formed apart from each other along the stripe direction of the gate electrode.

15. The semiconductor device according to claim 11, wherein the mesa contact portion includes
a second contact portion that is formed by the impurity region across its entirety in a thickness direction from the mesa upper portion, and in which the impurity region is exposed from both the mesa upper portion and the mesa side portion, and
a third contact portion that is formed across its entirety in the thickness direction from the mesa upper portion, is connected to the body region at a lower portion of the mesa contact portion, and is formed by a body contact region of the second conductivity type exposed from both the mesa upper portion and the mesa side portion.

16. The semiconductor device according to claim 15, wherein the second contact portion and the third contact portion are formed apart from each other along the stripe direction of the gate electrode.

17. The semiconductor device according to claim 1, wherein the chip is an SiC chip.
